(19) United States
(12) Patent Application Publication
(10) Pub. No.: US 2012/0319113 A1
(43) Pub. Date: Dec. 20, 2012

(54) SEMICONDUCTOR DEVICE AND METHOD FOR MANUFACTURING THE SAME

(75) Inventor: Shunpei YAMAZAKI, Setagaya (JP)

(73) Assignee: SEMICONDUCTOR ENERGY LABORATORY CO., LTD., Atsugi-shi (JP)

(21) Appl. No.: 13/484,740

(22) Filed: May 31, 2012

(30) Foreign Application Priority Data
Jun. 17, 2011 (JP) 2011-134971

(51) Int. Cl. H01L 29/786; H01L 21/44

(52) U.S. Cl. 257/57; 257/66; 438/151; 257/43; 257/E29.296; 257/E21.46

(57) ABSTRACT

At least part of the oxide semiconductor layer which serves as the channel formation region is thinned by etching and the thickness of the channel formation region is adjusted by the etching. Further, a dopant containing phosphorus (P) or boron (B) is introduced into a thick region of the oxide semiconductor layer to form a source region and a drain region in the oxide semiconductor layer, so that the contact resistance between the source and drain regions and the channel formation region which are connected to each other is reduced.

### BACKGROUND OF THE INVENTION

1. Field of the Invention

An embodiment of the present invention relates to a semiconductor device including a transistor or including a circuit including a transistor. For example, an embodiment of the present invention relates to a semiconductor device including a transistor in which a channel formation region is formed using an oxide semiconductor or including a circuit including such a transistor. For example, the present invention relates to an electronic device which includes, as a component, an LSI, a CPU, a power device mounted in a power circuit; a semiconductor integrated circuit including a memory, a thyristor, a converter, an image sensor, or the like; an electro-optical device typified by a liquid crystal display panel; or a light-emitting display device including a light-emitting element.

In this specification, a semiconductor device generally means a device which can function by utilizing semiconductor characteristics, and an electro-optical device, a semiconductor circuit, and electronic device are all semiconductor devices.

2. Description of the Related Art

In recent years, semiconductor devices have been developed to be used as an LSI, a CPU, or a memory. A CPU is an aggregation of semiconductor elements each provided with an electrode which is a connection terminal, which includes a semiconductor integrated circuit (including at least a transistor and a memory) separated from a semiconductor wafer.

A semiconductor circuit (IC chip) of an LSI, a CPU, or a memory is mounted on a circuit board, for example, a printed wiring board, to be used as one of components of a variety of electronic devices.

A technique for manufacturing a transistor or the like by using an oxide semiconductor for a channel formation region has been attracting attention. Examples of such a transistor include a transistor in which zinc oxide (ZnO) is used as an oxide semiconductor and a transistor in which InGaO₃(ZnO)ₘ is used as an oxide semiconductor. A technique for manufacturing such a transistor including an oxide semiconductor over a light-transmitting substrate and applying it to a switching element or the like of an image display device is disclosed in Patent Documents 1 and 2.

### REFERENCE

### [Patent Document 1] Japanese Published Patent Application No. 2007-123861

### [Patent Document 2] Japanese Published Patent Application No. 2007-096055

### SUMMARY OF THE INVENTION

When an n-channel transistor is used, it is preferable that a channel be formed at a positive threshold voltage (Vth) which is as close to 0 V as possible in the transistor. If the threshold voltage of the transistor is negative, the transistor tends to be in a so-called normally-on state, in which current flows between the source electrode and the drain electrode even when the gate voltage is 0 V. Electric characteristics of a transistor included in a circuit are significant in an LSI, a CPU, and a memory, and impact the performance of a semiconductor device. Among the electric characteristics of transistors, in particular, threshold voltage is important. When the threshold voltage is negative even when field effect mobility is high, it is difficult to control the circuit. Such a transistor in which a channel is formed even at a negative voltage so that a drain current flows is not suitable as a transistor used in an integrated circuit of a semiconductor device.

In order to achieve high-speed operation, low power consumption, high integration, cost reduction, or the like of a transistor, it is necessary to miniaturize a transistor. In the case where a transistor is miniaturized, a problem of a short-channel effect is caused. The short-channel effect refers to degradation of electric characteristics which becomes obvious along with miniaturization of a transistor (a decrease in channel length). The short-channel effect results from the effect of an electric field of a drain on a source. Specific examples of the short-channel effect are a decrease in threshold voltage, an increase in subthreshold swing (S value), an increase in leakage current, and the like. The short-channel effect is likely to occur particularly in a transistor including an oxide semiconductor because it is difficult to control the threshold voltage of such a transistor by doping.

Further, in the case of a transistor having a structure in which a source electrode layer and a drain electrode layer are directly in contact with an oxide semiconductor layer used for a channel formation region, contact resistance might be increased and on-state current might be reduced. One of factors causing high contact resistance is Schottky junction that is formed at the interface between the oxide semiconductor layer and the source and drain electrode layers.

In view of the problems, an object of one embodiment of the disclosed invention is to provide a semiconductor device in which the threshold voltage (Vth) of the electric characteristics of a transistor can be positive while a short-channel effect due to miniaturization of the transistor is suppressed, i.e., a so-called normally-off semiconductor device, and a method for manufacturing the semiconductor device. Another object of one embodiment of the disclosed invention is to provide a semiconductor device in which the contact resistance between source and drain regions and a channel formation region is reduced to obtain an excellent ohmic contact can be obtained, and a method for manufacturing the semiconductor device.

To achieve the objects, in the semiconductor device according to one embodiment of the present invention, at least part of the oxide semiconductor layer which serves as a channel formation region is thinned by etching and the thickness of the channel formation region is adjusted by the etching. Further, a dopant containing phosphorus (P) or boron (B) is introduced into a thick region of the oxide semiconductor layer to form a source region and a drain region in the oxide semiconductor layer, so that the contact resistance between the source and drain regions and the channel formation region which are connected to each other is reduced. Details of the semiconductor device are described below.

One embodiment of the present invention is a semiconductor device including an oxide semiconductor layer over an oxide insulating surface, a gate insulating layer over the oxide semiconductor layer, a gate electrode layer over the gate insulating layer, and a source region and a drain region in part of the oxide semiconductor layer. A region of the oxide semiconductor layer overlapping with the gate electrode layer is thinner than a region of the oxide semiconductor layer where the source region and the drain region are formed.

In the above structure, the thin region of the oxide semiconductor layer preferably includes a channel formation region overlapping with the gate electrode layer.

Since the region of the oxide semiconductor layer where the channel formation region is included is thin, the threshold voltage (Vth) can be adjusted in the positive direction while a short-channel effect is suppressed. Thus, a normally-off semiconductor device can be obtained.

One embodiment of the present invention is a semiconductor device including an oxide semiconductor layer over an oxide insulating surface, a gate insulating layer over the oxide semiconductor layer, a gate electrode layer over the gate insulating layer, and a source region and a drain region in part of the oxide semiconductor layer. In the semiconductor device, a region of the oxide semiconductor layer overlapping with the gate electrode layer is thinner than a region of the oxide semiconductor layer where the source region and the drain region are formed. The thin region of the oxide semiconductor layer includes a channel formation region overlapping with the gate electrode layer and a low-resistance region which is in contact with the channel formation region and has lower resistance than the channel formation region. The low-resistance region includes phosphorus or boron.

Since the low-resistance region is provided to be in contact with the channel formation region, the contact resistance between the channel formation region and the source and drain regions can be reduced. Thus, ON characteristics (e.g., on-state current, field effect mobility), which constitutes one of the chief electric characteristics of a transistor, is high and high-speed operation and high-speed response become possible.

Another embodiment of the present invention is a semiconductor device including an oxide semiconductor layer over an oxide insulating surface, a gate insulating layer over the oxide semiconductor layer, a gate electrode layer over the gate insulating layer, and a source region and a drain region in part of the oxide semiconductor layer. In the semiconductor device, a region of the oxide semiconductor layer overlapping with the gate electrode layer is thinner than a region of the oxide semiconductor layer where the source region and the drain region are formed. The thin region of the oxide semiconductor layer includes a channel formation region overlapping with the gate electrode layer. End portions of the thin region of the oxide semiconductor layer are aligned with end portions of the gate electrode layer.

Note that in this specification and the like, the expression “end portion of the oxide semiconductor layer” is a portion in the channel-length direction of the transistor. Further, the expression “end portions of the thin region of the oxide semiconductor layer are aligned with end portions of the gate electrode layer” means that, in the channel formation region, the end portions of the gate electrode layer are aligned with end portions of the source region and the drain region which are in contact with the channel formation region. With such a structure, an electric field can be efficiently applied to the channel formation region.

In the above structure, metal layers in contact with the source region and the drain region are preferably provided. End portions of the metal layers may be aligned with or on an inner side than the end portions of the thick regions of the oxide semiconductor layer.

When the metal layers in contact with the source region and the drain region are provided, the resistance of the source region and the drain region can be further reduced. In addition, in the case where the end portions of the metal layers are on the inner side than the end portions of the thick regions of the oxide semiconductor layer, parasitic capacitance between the metal layer and the gate electrode layer can be reduced.

Another embodiment of the present invention is a method for manufacturing a semiconductor device including the following steps: forming an oxide semiconductor layer over an oxide insulating surface; forming a mask over the oxide semiconductor layer; selectively etching the oxide semiconductor layer with the use of the mask to form a thin region in part of the oxide semiconductor layer; forming a gate insulating layer covering the oxide semiconductor layer; and forming a gate electrode layer overlapping with the thin region of the oxide semiconductor layer, over the gate insulating layer.

In such a manner, the gate electrode layer is formed at the end of the process (so-called gate-last process), so that when heat treatment or the like at high temperature is performed on the oxide semiconductor layer, damage due to the heat treatment on the gate electrode layer can be suppressed. Thus, there is a wider choice of materials for the gate electrode layer. For example, a low-melting-point metal such as aluminum can also be used for the gate electrode layer.

Another embodiment of the present invention is a method for manufacturing a semiconductor device including the following steps: forming an oxide semiconductor layer over an oxide insulating surface; forming a mask over the oxide semiconductor layer; selectively etching the oxide semiconductor layer with the use of the mask to form a thin region in part of the oxide semiconductor layer; forming a gate insulating layer covering the oxide semiconductor layer; forming a gate electrode layer overlapping with the thin region of the oxide semiconductor layer, over the gate insulating layer; and introducing phosphorus or boron into the oxide semiconductor layer through the gate insulating layer, with the use of the gate electrode layer as a mask to form a source region and a drain region in part of the oxide semiconductor layer in a self-aligned manner.

Since phosphorus or boron is introduced into the oxide semiconductor layer with the use of the gate electrode layer as a mask, the source region and the drain region whose resistance is lower than the channel formation region can be formed in part of the oxide semiconductor layer. Specifically, in the case where the oxide semiconductor layer includes gallium as a component, boron is preferably used. Since boron is an element belonging to the same group as gallium (Group 13 element), which is the element included in the oxide semiconductor layer, boron can exist stably in the oxide semiconductor layer.

Another embodiment of the present invention is a method for manufacturing a semiconductor device including the following steps: forming a stack of an oxide semiconductor layer and a metal layer over an oxide insulating surface; forming a mask over the metal layer; removing part of the metal layer with the use of the mask, and then, selectively etching the oxide semiconductor layer with the use of the metal layer as a mask so that a thin region is formed in part of the oxide semiconductor layer; forming a gate insulating layer covering the metal layer and the oxide semiconductor layer; forming a gate electrode layer overlapping with the thin region of the oxide semiconductor layer, over the gate insulating layer; and introducing phosphorus or boron into the oxide semiconductor layer through the gate insulating layer and the metal layer, with the use of the gate electrode layer as a mask to form a source region and a drain region in part of the oxide semiconductor layer in a self-aligned manner.

With the metal layer in contact with the source region and the drain region, the resistance of the source region and the drain region can be further reduced. Further, phosphorus or boron is introduced into the oxide semiconductor layer through the gate insulating layer and the metal layer and then, heat treatment is performed, whereby the metal layer is reacted with and/or diffused into the oxide semiconductor layer. Thus, the resistance of the source region and the drain region can be further reduced.

In each of the above structures, oxygen is preferably introduced into the oxide semiconductor layer through the gate insulating layer after the gate insulating layer is formed.

In that case, oxygen can be supplied to the oxide semiconductor layer. Note that when the gate insulating layer is thin, the amount of oxygen contained in the gate insulating layer is small, and thus, oxygen is not sufficiently supplied and diffused to the oxide semiconductor layer from the gate insulating layer. For this reason, oxygen is preferably introduced into the oxide semiconductor layer after the gate insulating layer is formed.

A semiconductor device in which the threshold voltage (Vth) of the electric characteristics of a transistor can be positive while a short-channel effect due to miniaturization of the transistor is suppressed, i.e., a so-called normally-off semiconductor device, and a method for manufacturing the semiconductor device can be provided.

A semiconductor device in which the contact resistance between source and drain regions and a channel formation region is reduced to obtain an excellent ohmic contact can be obtained, and a method for manufacturing the semiconductor device can be provided.

### BRIEF DESCRIPTION OF THE DRAWINGS

FIGS. 1A to 1C are diagrams illustrating embodiments of a semiconductor device.

FIGS. 2A to 2D are views illustrating an embodiment of a method for manufacturing the semiconductor device.

FIGS. 3A to 3D are views illustrating an embodiment of the method for manufacturing the semiconductor device.

FIGS. 4A and 4B are diagrams illustrating embodiments of a semiconductor device.

FIGS. 5A to 5D are diagrams illustrating an embodiment of a method for manufacturing the semiconductor device.

FIGS. 6A to 6D are diagrams illustrating an embodiment of the method for manufacturing the semiconductor device.

FIGS. 7A to 7C are diagrams illustrating an embodiment of a semiconductor device.

FIGS. 8A to 8F are diagrams illustrating electronic devices.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiments.

In addition, in this specification and the like, the term such as “electrode” or “wiring” does not limit a function of a component. For example, an “electrode” is sometimes used as part of a “wiring”, and vice versa. Furthermore, the term “electrode” or “wiring” can include the case where a plurality of “electrodes” or “wirings” is formed in an integrated manner.

Functions of a “source” and a “drain” are sometimes replaced with each other when a transistor of opposite polarity is used or when the direction of current flowing is changed in circuit operation, for example. Therefore, the terms “source” and “drain” can be used to denote the drain and the source, respectively, in this specification.

### Embodiment 1

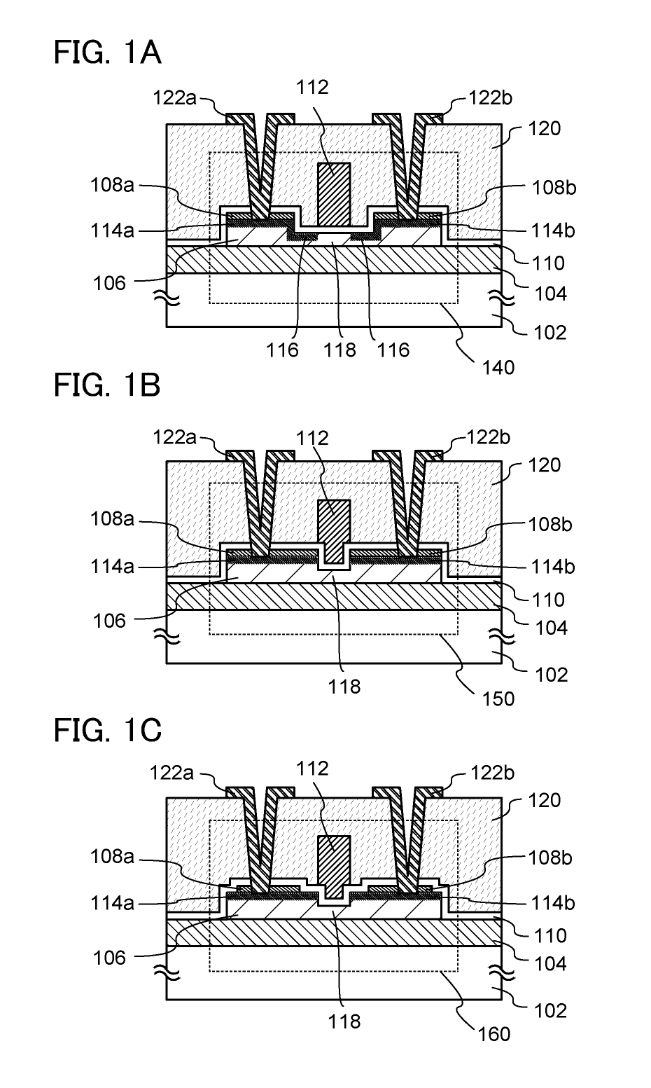

In this embodiment, a mode of a semiconductor device according to the present invention is described with reference to FIGS. 1A to 1C. In this embodiment, an example of the semiconductor device is described with reference to cross-sectional views of a transistor including an oxide semiconductor layer.

FIGS. 1A, 1B, and 1C are cross-sectional views of transistors 140, 150, and 160, respectively. Note that the transistors 140 to 160 are top-gate top-contact transistors (so called TGTC transistor), which can be seen from a position of a gate electrode layer with respect to a semiconductor layer (an oxide semiconductor layer in this specification), positions of source and drain regions to the semiconductor layer, and positions of the wiring layers, which are in contact with the source and drain regions, with respect to the source and drain regions. Structures of the transistors are described below.

The transistor 140 in FIG. 1A includes a substrate 102; an oxide insulating layer 104 over the substrate 102; an oxide semiconductor layer 106 formed over the oxide insulating layer 104 and including a channel formation region 118, low-resistance regions 116, a source region 114a, and a drain region 114b; metal layers 108a and 108b in contact with the source region 114a and the drain region 114b, respectively; a gate insulating layer 110 over the oxide insulating layer 104, the oxide semiconductor layer 106, and the metal layers 108a and 108b; and a gate electrode layer 112 over the gate insulating layer 110.

Note that in the oxide semiconductor layer 106, a region overlapping with the gate electrode layer 112 is thinner than regions where the source region 114a and the drain region 114b (hereinafter, respectively referred to as “a thin region of the oxide semiconductor layer 106” and “thick regions of the oxide semiconductor layer 106” for convenience) are formed. The oxide semiconductor layer 106 includes the pair of low-resistance regions 116, the channel formation region 118 sandwiched between the pair of low-resistance regions 116, and the source region 114a and the drain region 114b which are in contact with the pair of low-resistance regions. The pair of low-resistance regions 116 is formed in the thin region of the oxide semiconductor layer 106. The source region 114a and the drain region 114b are formed in the thick regions of the oxide semiconductor layer 106 to be in contact with the metal layers 108a and 108b, respectively.

The thin region of the oxide semiconductor layer 106 can be formed by an etching process. For example, an oxide semiconductor layer is formed with a thickness of 15 nm to 30 nm and is then etched to have about 5 nm. Since the channel formation region 118 is formed in the oxide semiconductor layer 106 with such a thickness, a short-channel effect due to miniaturization of the transistor can be reduced. The thin region of the oxide semiconductor layer 106 can be formed by etching process. The channel formation region 118 can be formed in the thin region, and the source and drain regions 114a and 114b can be formed in the thick regions. With such a structure, the contact resistance between the channel formation region 118 and the source and drain regions 114a and 114b, which increases as the thickness of the oxide semiconductor layer 106 decreases, can be reduced.

Further, the pair of low-resistance regions 116, the source region 114a, and the drain region 114b which are included in the oxide semiconductor layer 106 have a resistance lower than the channel formation region 118 and include phosphorus (P) or boron (B). For example, the gate electrode layer 112 is formed and then a dopant containing phosphorus (P) or boron (B) is introduced into the oxide semiconductor layer 106 (impurity introduction), so that these low-resistance regions can be formed in a self-aligned manner. Note that a “dopant” is an impurity to reduce the resistance of the oxide semiconductor layer.

In addition, since the pair of low-resistance regions 116 is provided between the channel formation region 118 and the source and drain regions 114a and 114b, a negative shift of the threshold voltage due to a short-channel effect can be reduced.

The source region 114a and the drain region 114b can be formed as follows: heat treatment or the like is performed in a state where the oxide semiconductor layer 106 is in contact with the metal layers 108a and 108b, whereby the metal layers 108a and 108b are reacted with and/or diffused into the oxide semiconductor layer 106. A further reduction in the resistance of the source region 114a and the drain region 114b can be achieved owing to the provision of the metal layers 108a and 108b in addition to the impurity introduction.

Further, the transistor 140 may include a protective layer 120 over the gate insulating layer 110 and the gate electrode layer 112; and wiring layers 122a and 122b, respectively in contact with the source region 114a and the drain region 114b, through openings formed in the protective layer 120, the gate insulating layer 110, and the metal layers 108a and 108b. Since the protective layer 120 and the wiring layers 122a and 122b are formed over the transistor 140, the transistors 140 can be integrated. The protective layer 120 is preferably provided, in which case, unevenness of the transistor 140 can be suppressed or entry of impurities (e.g., water) into the transistor 140 can be suppressed.

Next, a mode different from the transistor 140 in FIG. 1A is described with reference to FIG. 1B.

The transistor 150 in FIG. 1B includes a substrate 102; an oxide insulating layer 104 over the substrate 102; an oxide semiconductor layer 106 formed over the oxide insulating layer 104 and including a channel formation region 118, a source region 114a, and a drain region 114b; metal layers 108a and 108b in contact with the source region 114a and the drain region 114b, respectively; a gate insulating layer 110 over the oxide insulating layer 104, the oxide semiconductor layer 106, and the metal layers 108a and 108b; and a gate electrode layer 112 over the gate insulating layer 110.

Note that in the oxide semiconductor layer 106, the region overlapping with the gate electrode layer 112 is thinner than the regions where the source region 114a and the drain region 114b are formed. End portions of the thin region of the oxide semiconductor layer 106 are aligned with the end portions of the gate electrode layer 112.

Further, the source region 114a and the drain region 114b which are included in the oxide semiconductor layer 106 have a resistance lower than the channel formation region 118 and include phosphorus (P) or boron (B). For example, the gate electrode layer 112 is formed and then a dopant containing phosphorus (P) or boron (B) is introduced into the oxide semiconductor layer 106 (impurity introduction), so that these low-resistance regions can be formed in a self-aligned manner. Note that a “dopant” is an impurity to reduce the resistance of the oxide semiconductor layer.

The thin region of the oxide semiconductor layer 106 can be formed by an etching process. For example, an oxide semiconductor layer is formed with a thickness of 15 nm to 30 nm and is then etched to have about 5 nm. Since the channel formation region 118 is formed in the oxide semiconductor layer 106 with such a thickness, a short-channel effect due to miniaturization of the transistor can be reduced. The thin region of the oxide semiconductor layer 106 can be formed by etching process. The channel formation region 118 can be formed in the thin region, and the source and drain regions 114a and 114b can be formed in the thick regions. With such a structure, the contact resistance between the channel formation region 118 and the source and drain regions 114a and 114b, which increases as the thickness of the oxide semiconductor layer 106 decreases, can be reduced.

The source region 114a and the drain region 114b can be formed as follows: heat treatment or the like is performed in a state where the oxide semiconductor layer 106 is in contact with the metal layers 108a and 108b, whereby the metal layers 108a and 108b are reacted with and/or diffused into the oxide semiconductor layer 106. A further reduction in the resistance of the source region 114a and the drain region 114b can be achieved owing to the provision of the metal layers 108a and 108b in addition to the impurity introduction.

Further, the transistor 150 may include a protective layer 120 over the gate insulating layer 110 and the gate electrode layer 112; and wirings 122a and 122b, respectively in contact with the source region 114a and the drain region 114b, through openings formed in the protective layer 120, the gate insulating layer 110, and the metal layers 108a and 108b. Since the protective layer 120 and the wiring layers 122a and 122b are formed over the transistor 150, the transistors 150 can be integrated. The protective layer 120 is preferably provided, in which case, unevenness of the transistor 150 can be suppressed or entry of impurities (e.g., water) into the transistor 150 can be suppressed.

Note that structure differences between the transistor 150 in FIG. 1B and the transistor 140 in FIG. 1A are that the shape of the thin region of the oxide semiconductor layer 106 and whether or not the pair of low-resistance regions 116 is provided. That is, in the transistor 140 in FIG. 1A, the channel formation region 118 and the pair of low-resistance regions 116 are formed in the thin region of the oxide semiconductor layer 106, whereas in the transistor 150 in FIG. 1B, only the channel formation region 118 is formed in the thin region of the oxide semiconductor layer 106. The end portions of the thin region of the oxide semiconductor layer 106 are aligned with the end portions of the gate electrode layer 112. In other words, in the channel formation region 118, the end portions of the gate electrode layer 112 and the source and drain regions 114a and 114b are aligned. With such a structure, an electric field can be efficiently applied to the channel formation region 118.

Next, a mode different from the transistor 140 in FIG. 1A and the transistor 150 in FIG. 1B is described with reference to FIG. 1C.

The transistor 160 in FIG. 1C includes a substrate 102; an oxide insulating layer 104 over the substrate 102; an oxide semiconductor layer 106 formed over the oxide insulating layer 104 and including a channel formation region 118, a source region 114a, and a drain region 114b; metal layers 108a and 108b in contact with the source region 114a and the drain region 114b, respectively; a gate insulating layer 110 over the oxide insulating layer 104, the oxide semiconductor layer 106, and the metal layers 108a and 108b; and a gate electrode layer 112 over the gate insulating layer 110.

Note that in the oxide semiconductor layer 106, the region overlapping with the gate electrode layer 112 is thinner than the regions where the source region 114a and the drain region 114b are formed. The metal layers 108a and 108b are formed over the thick regions of the oxide semiconductor layer 106. The end portions of the metal layers 108a and 108b are placed on the inner side than the end portions of the thick regions of the oxide semiconductor layer 106.

Further, the source region 114a and the drain region 114b which are included in the oxide semiconductor layer 106 have a resistance lower than the channel formation region 118 and include phosphorus (P) or boron (B). For example, the gate electrode layer 112 is formed and then a dopant containing phosphorus (P) or boron (B) is introduced into the oxide semiconductor layer 106 (impurity introduction), so that these low-resistance regions can be formed in a self-aligned manner. Note that a “dopant” is an impurity to reduce the resistance of the oxide semiconductor layer.

The thin region of the oxide semiconductor layer 106 can be formed by an etching process. For example, an oxide semiconductor layer is formed with a thickness of 15 nm to 30 nm and is then etched to have about 5 nm. Since the channel formation region 118 is formed in the oxide semiconductor layer 106 with such a thickness, a short-channel effect due to miniaturization of the transistor can be reduced. The thin region of the oxide semiconductor layer 106 can be formed by etching process. The channel formation region 118 can be formed in the thin region, and the source and drain regions 114a and 114b can be formed in the thick regions. With such a structure, the contact resistance between the channel formation region 118 and the source and drain regions 114a and 114b, which increases as the thickness of the oxide semiconductor layer 106 decreases, can be reduced.

The source region 114a and the drain region 114b can be formed as follows: heat treatment or the like is performed in a state where the oxide semiconductor layer 106 is in contact with the metal layers 108a and 108b, whereby the metal layers 108a and 108b are reacted with and/or diffused into the oxide semiconductor layer 106. A further reduction in the resistance of the source region 114a and the drain region 114b can be achieved owing to the provision of the metal layers 108a and 108b in addition to the impurity introduction.

Further, the transistor 160 may include a protective layer 120 over the gate insulating layer 110 and the gate electrode layer 112; and wiring layers 122a and 122b, respectively in contact with the source region 114a and the drain region 114b, through openings formed in the protective layer 120, the gate insulating layer 110, and the metal layers 108a and 108b. Since the protective layer 120 and the wiring layers 122a and 122b are formed over the transistor 160, the transistors 160 can be integrated. The protective layer 120 is preferably provided, in which case, unevenness of the transistor 160 can be suppressed or entry of impurities (e.g., water) into the transistor 160 can be suppressed.

Note that a structure difference between the transistor 160 in FIG. 1C and the transistor 150 in FIG. 1B is the shape of the metal layers 108a and 108b with respect to the oxide semiconductor layer 106. In the transistor 160, the end portions of the metal layers 108a and 108b are placed on the inner side than the end portions of the thick regions of the oxide semiconductor layer 106. Such a structure is effective in improving step coverage of the gate insulating layer 110. Even when the gate electrode layer 112 is formed to be displaced, the gate electrode layer 112 much less likely to overlap with the metal layers 108a and 108b, which is preferable. Further, the parasitic capacitance between the metal layers 108a and 108b and the gate electrode layer 112 can be reduced.

As described above, the semiconductor devices in FIGS. 1A to 1C have in common that the semiconductor layer is formed using an oxide semiconductor layer, and that the oxide semiconductor layer at least serving as a channel formation region is partly etched and thinned in order to adjust the thickness of the channel formation region. Since the region of the oxide semiconductor layer where the channel formation region is included is thin, the threshold voltage (Vth) can be adjusted in the positive direction while a short-channel effect is suppressed. Thus, a normally-off semiconductor device can be obtained.

In the semiconductor device in FIGS. 1A to 1C, a dopant containing phosphorus (P) or boron (B) is introduced into a thick region of the oxide semiconductor layer to form a source region and a drain region in the oxide semiconductor layer, so that the contact resistance between the source and drain regions and the channel formation region which are connected to each other can be reduced. Thus, the semiconductor device with a high on-state current can be obtained.

This embodiment can be combined with any of the other embodiments as appropriate.

### Embodiment 2

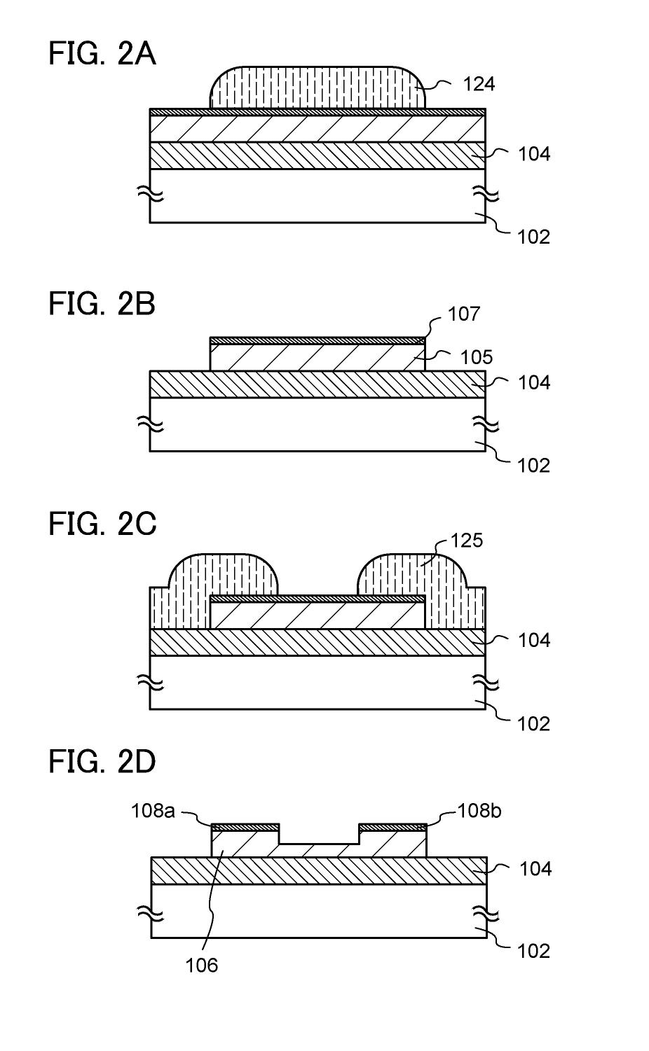

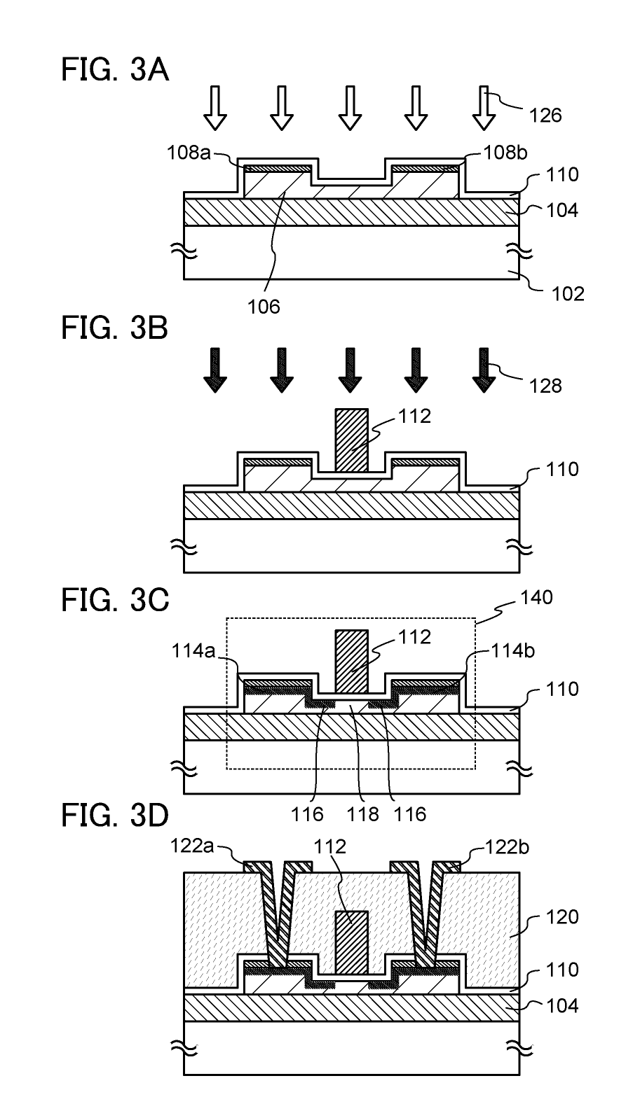

In this embodiment, a method for manufacturing the transistor 140 described in Embodiment 1 with reference to FIG. 1A is specifically described with reference to FIGS. 2A to 2D and FIGS. 3A to 3D. Note that portions similar to those in FIGS. 1A to 1C are denoted by the same reference numerals, and description thereof is skipped.

First, the oxide insulating layer 104 is formed over the substrate 102 and then, an oxide semiconductor film and a metal film are formed over the oxide insulating layer 104. Then, a resist mask 124 is formed over a desired region of the metal film (see FIG. 2A).

Although there is no particular limitation on a material which can be used for the substrate 102, it is necessary that the material have at least heat resistance high enough to withstand heat treatment to be performed later. For example, a glass substrate of barium borosilicate glass, aluminoborosilicate glass, or the like, a ceramic substrate, a quartz substrate, or a sapphire substrate can be used. A single crystal semiconductor substrate or a polycrystalline semiconductor substrate formed of silicon, silicon carbide, or the like; a compound semiconductor substrate of silicon germanium or the like; an SOI substrate; or the like can be used as the substrate 102, or the substrate provided with a semiconductor element can be used as the substrate 102.

The oxide insulating layer 104 can be formed by a plasma CVD method, a sputtering method, or the like using silicon oxide, silicon oxynitride, aluminum oxide, aluminum oxynitride, hafnium oxide, gallium oxide, silicon nitride oxide, aluminum nitride oxide, or a mixed material thereof. A silicon oxide film is formed by a sputtering method as the oxide insulating layer 104 in this embodiment.

The oxide insulating layer 104 is in contact with the oxide semiconductor film and therefore preferably contains a large amount of oxygen which exceeds at least the stoichiometry in (a bulk of) the film. For example, in the case where a silicon oxide film is used as the oxide insulating layer 104, the composition formula is SiO_{2+α} (α>0). With the oxide insulating layer 104 thus formed, oxygen can be supplied to the oxide semiconductor film, whereby oxygen vacancies in the film can be compensated.

In order to prevent the oxide semiconductor film from containing hydrogen or water as much as possible in the step of forming the oxide semiconductor film, it is preferable to preheat the substrate 102 provided with the oxide insulating layer 104 in a preheating chamber of a sputtering apparatus before the formation of the oxide semiconductor film so that an impurity such as hydrogen and moisture adsorbed on the substrate 102 and the oxide insulating layer 104 is eliminated and expelled from the chamber. As an exhaustion unit provided in the preheating chamber, a cryopump is preferable.

The oxide semiconductor film preferably contains at least indium (In) or zinc (Zn). In particular, In and Zn are preferably contained. As a stabilizer for reducing change in electric characteristics of a transistor including the oxide, gallium (Ga) is preferably additionally contained. Tin (Sn) is preferably contained as a stabilizer. Hafnium (Hf) is preferably contained as a stabilizer. Aluminum (Al) is preferably contained as a stabilizer.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

For the oxide semiconductor film, for example, the following can be used: indium oxide, tin oxide, zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Note that here, for example, an “In—Ga—Zn-based oxide” means an oxide containing In, Ga, and Zn as main components and there is no particular limitation on the ratio of In, Ga, and Zn. Further, the In—Ga-Z-based oxide may contain a metal element other than In, Ga, and Zn.

For the oxide semiconductor film, a material expressed as the chemical formula InMO₃(ZnO)ₘ (m>0, m is not an integer) may be used. Note that M represents one or more metal elements selected from Ga, Fe, Mn, and Co. Alternatively, as the oxide semiconductor, a material expressed by a chemical formula, In₂SnO₅(ZnO)ₙ (n>0, n is a natural number) may be used.

For example, an In—Ga—Zn-based oxide with an atomic ratio of In:Ga:Zn=1:1:1 (=1/3:1/3:1/3) or In:Ga:Zn=2:2:1 (=2/5:2/5:1/5), or any of oxides whose composition is in the neighborhood of the above compositions can be used. Alternatively, an In—Sn—Zn-based oxide with an atomic ratio of In:Sn:Zn=1:1:1 (=1/3:1/3:1/3), In:Sn:Zn=2:1:3 (=1/3:1/6:1/2), or In:Sn:Zn=2:1:5 (=1/4:1/8:5/8), or any of oxides whose composition is in the neighborhood of the above compositions may be used.

Note that one embodiment of the present invention is not limited thereto, and a material having appropriate composition depending on semiconductor characteristics (mobility, threshold, variation, and the like) may be used. Further, it is preferable to appropriately set the carrier concentration, the impurity concentration, the defect density, the atomic ratio of a metal element and oxygen, the interatomic distance, the density, or the like in order to obtain necessary semiconductor characteristics.

For example, high mobility can be obtained relatively easily in the case of using an In—Sn—Zn oxide. Even when the In—Ga—Zn-based oxide is used, the mobility can be increased by reducing the bulk defect density.

Note that for example, the expression “the composition of an oxide including In, Ga, and Zn at the atomic ratio, In:Ga:Zn=a:b:c (a+b+c=1), is in the neighborhood of the composition of an oxide including In, Ga, and Zn at the atomic ratio, In:Ga:Zn=A:B:C (A+B+C=1)” means that a, b, and c satisfy the following relation: (a−A)²+(b−B)²+(c−C)² r², and r may be 0.05, for example. The same applies to other oxides.

The oxide semiconductor film may be either single crystal or non-single-crystal. In the case where the oxide semiconductor film is non-single-crystal, the oxide semiconductor may be either amorphous or polycrystal. Further, the oxide semiconductor film may have either an amorphous structure including a portion having crystallinity or a non-amorphous structure.

It is relatively easy to make a surface of an amorphous oxide semiconductor film flat. Thus, when a transistor is manufactured with the use of the oxide semiconductor, interface scattering can be reduced, and relatively high mobility can be obtained relatively easily.

In the crystalline oxide semiconductor film including a crystalline oxide semiconductor, defects in the bulk can be further reduced, and mobility higher than that of an amorphous oxide semiconductor film can be obtained when a surface flatness is improved. In order to improve the surface flatness, the oxide semiconductor film is preferably formed on a flat surface. Specifically, the oxide semiconductor film is preferably formed on a surface with an average surface roughness (Ra) of less than or equal to 1 nm, preferably less than or equal to 0.3 nm, more preferably less than or equal to 0.1 nm.

Note that Ra is obtained by three-dimensionally expanding arithmetic average roughness that is defined by JIS B 0601:2001 (ISO4287:1997) so as to be able to be applied to a curved surface. Rₐ can be expressed as an “average value of the absolute values of deviations from a reference surface to a specific surface” and is defined by the following formula.

$$Ra = \frac{1}{{S}_{0}} {\int }_{{y}_{1}}^{{y}_{2}} {\int }_{{x}_{1}}^{{x}_{2}} \vert f ( x , y ) - {Z}_{0} \vert d x d y \qquad [ Formula 1 ]$$

Here, the specific surface is a surface which is a target of roughness measurement, and is a quadrilateral region which is specified by four points represented by the coordinates (x₁, y₁, f(x₁, y₁)), (x₁, y₂, f(x₁, y₂)), (x₂, y₁, f(x₂, y₁)), and (x₂, y₂, f(x₂, y₂)). S₀ represents the area of a rectangle which is obtained by projecting the specific surface on the xy plane, and Z₀ represents the height of the reference surface (the average height of the specific surface). Ra can be measured using an atomic force microscope (AFM).

Thus, planarization treatment may be performed on a region of the oxide insulating layer 104 which is in contact with the oxide semiconductor film. As the planarization treatment, polishing treatment (e.g., chemical mechanical polishing (CMP)), dry-etching treatment, or plasma treatment can be used, though there is no particular limitation on the planarization treatment.

As the plasma treatment, a reverse sputtering in which an argon gas is introduced and plasma is produced can be performed. The reverse sputtering is a method in which voltage is applied to a substrate side with the use of an RF power source in an argon atmosphere and plasma is generated in the vicinity of the substrate so that the substrate surface is modified. Note that instead of an argon atmosphere, a nitrogen atmosphere, a helium atmosphere, an oxygen atmosphere, or the like may be used. The reverse sputtering can remove particle substances (also referred to as particles or dust) attached to the top surface of the oxide insulating layer 104.

As the planarization treatment, polishing treatment, dry etching treatment, or plasma treatment may be performed plural times, or these treatments may be performed in combination. In the case where the treatments are combined, the order of steps is not particularly limited and may be set as appropriate depending on the roughness of the surface of the oxide insulating layer 104.

An oxide semiconductor film having crystallinity (a crystalline oxide semiconductor film) may be used as the oxide semiconductor film. The crystals in the crystalline oxide semiconductor film may have crystal axes oriented in random directions or in a certain direction.

It is preferable to use a CAAC-OS (c-axis aligned crystalline oxide semiconductor) film as the crystalline oxide semiconductor film, for example.

The CAAC-OS film is not completely single crystal nor completely amorphous. The CAAC-OS film is an oxide semiconductor film with a crystal-amorphous mixed phase structure where crystal parts are included in an amorphous phase. Note that in most cases, the crystal part fits inside a cube whose one side is less than 100 nm. From an observation image obtained with a transmission electron microscope (TEM), a boundary between an amorphous part and a crystal part in the CAAC-OS film is not clear. Further, with the TEM, a grain boundary in the CAAC-OS film is not found. Thus, in the CAAC-OS film, a reduction in electron mobility, due to the grain boundary, is suppressed.

In each of the crystal parts included in the CAAC-OS film, a c-axis is aligned in a direction parallel to a normal vector of a surface where the CAAC-OS film is formed or a normal vector of a surface of the CAAC-OS film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a simple term “perpendicular” includes a range from 85° to 95°. In addition, a simple term “parallel” includes a range from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film).

Note that when the CAAC-OS film is formed, the direction of c-axis of the crystal part is the direction parallel to a normal vector of the surface where the CAAC-OS film is formed or a normal vector of the surface of the CAAC-OS film. The crystal part is formed by film formation or by performing treatment for crystallization such as heat treatment after film formation.

With the use of the CAAC-OS film in a transistor, change in electric characteristics of the transistor due to irradiation with visible light or ultraviolet light can be reduced. Thus, the transistor has high reliability.

There are three methods for obtaining a CAAC-OS film when the CAAC-OS film is used as the oxide semiconductor film. First is a method in which an oxide semiconductor film is deposited at a temperature higher than or equal to 200° C. and lower than or equal to 500° C. such that the c-axis is substantially perpendicular to the top surface. Second is a method in which an oxide semiconductor film is deposited thin, and is subjected to heat treatment at a temperature higher than or equal to 200° C. and lower than or equal to 700° C., so that the c-axis is substantially perpendicular to the top surface. Third is a method in which a first-layer oxide semiconductor film is deposited thin, and is subjected to heat treatment at a temperature higher than or equal to 200° C. and lower than or equal to 700° C., and a second-layer oxide semiconductor film is deposited thereover, so that the c-axis is substantially perpendicular to the top surface.

The oxide semiconductor film has a thickness greater than or equal to 1 nm and less than or equal to 200 nm (preferably greater than or equal to 15 nm and less than or equal to 30 nm) and can be formed by a sputtering method, a molecular beam epitaxy (MBE) method, a CVD method, a pulse laser deposition method, an atomic layer deposition (ALD) method, or the like as appropriate. The oxide semiconductor film may be formed using a sputtering apparatus which performs deposition with top surfaces of a plurality of substrates set substantially perpendicular to a top surface of a sputtering target, which is a so-called columnar plasma (CP) sputtering system.

Note that it is preferable that the oxide semiconductor film be formed under a condition that much oxygen is contained during film formation (e.g., formed by a sputtering method in a 100% oxygen atmosphere), so as to be a film containing much oxygen (preferably having a region containing oxygen in excess of the stoichiometric ratio in the oxide semiconductor in a crystalline state).

The target used for formation of the oxide semiconductor film by a sputtering method is, for example, a metal oxide target having a composition ratio of In₂O₃:Ga₂O₃:ZnO=1:1:2[molar ratio], so that an In—Ga—Zn film is formed. Without limitation to the material and the composition of the above target, for example, a metal oxide target having a composition ratio of In₂O₃:Ga₂O₃:ZnO=1:1:1 [molar ratio] may be used.

The filling factor of the metal oxide target is greater than or equal to 90% and less than or equal to 100%, preferably greater than or equal to 95% and less than or equal to 99.9%. With the use of the metal oxide target with high filling factor, a dense oxide semiconductor film can be formed.

It is preferable that a high-purity gas from which an impurity such as hydrogen, water, a hydroxyl group, and hydride is removed be used as a sputtering gas for the formation of the oxide semiconductor film.

The substrate is held in a film formation chamber kept under reduced pressure. Then, a sputtering gas from which hydrogen and moisture are removed is introduced while residual moisture in the film formation chamber is removed, and the oxide semiconductor film is formed over the oxide insulating layer 104 using the above target. In order to remove moisture remaining in the film formation chamber, an entrapment vacuum pump such as a cryopump, an ion pump, or a titanium sublimation pump is preferably used. As an exhaustion unit, a turbo molecular pump to which a cold trap is added may be used. In the film formation chamber which is evacuated with the cryopump, a hydrogen atom, a compound containing a hydrogen atom, such as water (H₂O), (more preferably, also a compound containing a carbon atom), and the like are removed, whereby the concentration of impurities in the oxide semiconductor film formed in the film formation chamber can be reduced.

The oxide insulating layer 104 and the oxide semiconductor film are preferably formed in succession without exposure to the air. When the oxide insulating layer 104 and the oxide semiconductor film are formed in succession without exposure to the air, impurities such as hydrogen and moisture can be prevented from being adsorbed onto a surface of the oxide insulating layer 104.

Further, heat treatment may be performed on the oxide semiconductor film in order to remove excess hydrogen (including water and a hydroxyl group) (to perform dehydration or dehydrogenation). The temperature in the heat treatment is higher than or equal to 300° C. and lower than or equal to 700° C., or lower than the strain point of a substrate. The heat treatment can be performed under reduced pressure, a nitrogen atmosphere, or the like. For example, after the substrate is put in an electric furnace which is a kind of heat treatment apparatus, the oxide semiconductor film is subjected to heat treatment at 450° C. for one hour in a nitrogen atmosphere.

Further, a heat treatment apparatus used is not limited to an electric furnace, and a device for heating a process object by heat conduction or heat radiation from a heating element such as a resistance heating element may be alternatively used. For example, a rapid thermal anneal (RTA) apparatus such as a gas rapid thermal anneal (GRTA) apparatus or a lamp rapid thermal anneal (LRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the high-temperature gas, an inert gas which does not react with an object to be processed by heat treatment, such as nitrogen or a rare gas like argon, is used.

For example, as the heat treatment, GRTA may be performed as follows: the substrate is heated in an inert gas heated at high temperature of 650° C. to 700° C. for several minutes, and is taken out of the inert gas.

Such heat treatment for dehydration or dehydrogenation may be performed at any timing in the process of manufacturing the transistor 140 as long as it is performed between the formation of the oxide semiconductor layer 105 and the formation of the metal layers 108a and 108b.

The heat treatment for dehydration or dehydrogenation is preferably performed before the oxide semiconductor film is processed into an island-shaped oxide semiconductor layer 105 because oxygen contained in the oxide insulating layer 104 can be prevented from being released by the heat treatment.

Note that in the heat treatment, it is preferable that moisture, hydrogen, and the like be not contained in nitrogen or a rare gas such as helium, neon, or argon. The purity of nitrogen or the rare gas such as helium, neon, or argon which is introduced into the heat treatment apparatus is set to preferably 6N (99.9999%) or higher, more preferably 7N (99.99999%) or higher (that is, the impurity concentration is preferably 1 ppm or lower, more preferably 0.1 ppm or lower).

In addition, after the oxide semiconductor film is heated by the heat treatment, a high-purity oxygen gas, a high-purity N₂O gas, or the ultra-dry air (the moisture amount is 20 ppm or lower (−55° C. by conversion into a dew point), preferably 1 ppm or lower, more preferably 10 ppb or lower, in the measurement with the use of a dew point meter of a cavity ring down laser spectroscopy (CRDS) system) may be introduced into the same furnace. It is preferable that water, hydrogen, and the like be not contained in the oxygen gas or the N₂O gas. The purity of the oxygen gas or the N₂O gas that is introduced into the heat treatment apparatus is preferably greater than or equal to 6N, more preferably greater than or equal to 7N (i.e., the concentration of impurities in the oxygen gas or the N₂O gas is preferably less than or equal to 1 ppm, more preferably less than or equal to 0.1 ppm). The oxygen gas or the N₂O gas acts to supply oxygen that is a main component material of the oxide semiconductor and that is reduced by the step for removing impurities for the dehydration or dehydrogenation, so that the oxide semiconductor film can be a highly purified, electrically i-type (intrinsic) oxide semiconductor film.

As the metal film, for example, a metal film containing an element selected from Ta, W, Al, and Mo, a metal nitride film containing the element (a tantalum nitride film, a tungsten nitride film, an aluminum nitride film, or a molybdenum nitride film), or a metal oxide film containing the element (a tantalum oxide film, a tungsten oxide film, an aluminum oxide film, or a molybdenum oxide film) can be used. Alternatively, a stacked-layer structure in which any of these metal films, the metal nitride films, and the metal oxide films are combined may be used.

Note that the metal film preferably has a thickness with which a dopant can pass through the metal film, for example, preferably more than or equal to 1 nm and less than or equal to 50 nm, further preferably more than or equal to 1 nm and less than or equal to 30 nm.

As the resist mask 124, a photoresist is used, for example. There is a positive-type and a negative-type photoresist, and either can be used. The resist mask 124 can be formed with a thickness of greater than or equal to 0.5 μm and less than or equal to 5 μm using a photoresist with a spin-coater, a slit-coater, or the like, and after prebaking it, the photoresist is exposed to light with a wavelength with which the photoresist used is reacted. The resist mask 124 is preferably formed by an inkjet method, in which case a photomask is not used and thus manufacturing costs can be reduced.

Unnecessary regions of the metal film and the oxide semiconductor film are removed by an etching process with the use of the resist mask 124 as a mask and then, the resist mask 124 is removed; thus, the island-shaped oxide semiconductor layer 105 and an island-shaped metal layer 107 are formed (see FIG. 2B).

Note that the metal film and the oxide semiconductor film here may be etched by either dry etching or wet etching, or by both dry etching and wet etching. As an etchant used for wet etching of the oxide semiconductor film, for example, a mixed solution of phosphoric acid, acetic acid, and nitric acid, or the like can be used. In addition, ITO07N (produced by KANTO CHEMICAL CO., INC.) may also be used.

Next, a resist mask 125 is formed over the oxide insulating layer 104, the oxide semiconductor layer 105, and the metal layer 107 (see FIG. 2C).

The resist mask 125 can be formed using a method and a material similar to those of the resist mask 124.

Unnecessary regions of the metal layer 107 and the oxide semiconductor layer 105 are removed by an etching process with the use of the resist mask 125 as a mask, and then, the resist mask 125 is removed. The metal layer 107 is divided by the etching process, so that the metal layers 108a and 108b are formed. The oxide semiconductor layer 105 becomes an oxide semiconductor layer 106 with a thin region, through the etching process with the use of the resist mask 125 and the metal layers 108a and 108b as masks (see FIG. 2D).

Note that part of the thin region of the oxide semiconductor layer 106 becomes a channel formation region, and the thick regions of the oxide semiconductor layer 106 in contact with the metal layers 108a and 108b serve as a source region and a drain region. The thin region of the oxide semiconductor layer 106 needs to be thinner than at least the thick regions in contact with the metal layers 108a and 108b, and preferably has a thickness of greater than or equal to 1 nm and less than or equal to 10 nm, further preferably greater than or equal to 1 nm and less than or equal to 5 nm. Note that the thickness of the thin region of the oxide semiconductor layer 106 is not limited thereto and can be set as appropriate depending on a composition element and a deposition method of the oxide semiconductor or the size of a transistor (e.g., L/W size or L/W size).

Next, the gate insulating layer 110 is formed over the oxide insulating layer 104, the oxide semiconductor layer 106, and the metal layers 108a and 108b (see FIG. 3A).

The gate insulating layer 110 can be formed by a sputtering method, a plasma CVD method, or the like. For example, silicon oxide film, a gallium oxide film, an aluminum oxide film, a silicon nitride film, a silicon oxynitride film, an aluminum oxynitride film, or a silicon nitride oxide film can be formed by a plasma CVD method.

Note that the gate insulating layer 110 preferably includes oxygen in a portion which is in contact with the oxide semiconductor layer 106. In particular, the gate insulating layer 110 preferably contains a large amount of oxygen which exceeds at least the stoichiometry in (a bulk of) the layer. For example, in the case where a silicon oxide film is used as the gate insulating layer 110, the composition formula is SiO_{2+α} (α>0). In this embodiment, a silicon oxide film of SiO_{2+α} (α>0) is used as the gate insulating layer 110. By using the silicon oxide film as the gate insulating layer 110, oxygen can be supplied to the oxide semiconductor layer 106 and favorable characteristics can be obtained.

The gate insulating layer 110 can be formed using a high-k material such as hafnium oxide, yttrium oxide, hafnium silicate (HfSiₓO_{y} (x>0, y>0)), hafnium silicate to which nitrogen is added (HfSiOₓN_{y} (x>0, y>0)), hafnium aluminate (HfAlₓO_{y} (x>0, y>0)), or lanthanum oxide, whereby gate leakage current can be reduced. Further, the gate insulating layer 110 may have a single-layer structure or a stacked structure.

The thickness of the gate insulating layer 110 is preferably greater than or equal to 1 nm and less than or equal to 100 nm, further preferably greater than or equal to 1 nm and less than or equal to 30 nm. With the gate insulating layer 110 thinned, a short-channel effect can be suppressed. In this embodiment, as the gate insulating layer 110, a 15-nm-thick silicon oxide film is formed by a plasma CVD method.

Oxygen 126 is introduced into the oxide semiconductor layer 106 through the gate insulating layer 110 (see FIG. 3A).

The oxygen 126 (containing at least any of an oxygen radical, an oxygen atom, and an oxygen ion) is introduced into the oxide semiconductor layer 106 (oxygen introduction). Oxygen can be introduced by an ion implantation method, an ion doping method, a plasma immersion ion implantation method, plasma treatment, or the like.

For supply of oxygen to the oxide semiconductor layer, oxygen contained in the gate insulating layer 110 may be supplied to the oxide semiconductor layer 106; however, the amount of oxygen contained in the thin gate insulating layer 110 (15 nm) in this embodiment is smaller than in the case where the gate insulating layer is thick (e.g., 100 nm or more). Thus, there is a possibility that oxygen is not sufficiently supplied to the oxide semiconductor layer 106. For this reason, the oxygen introduction is performed as described in this embodiment so that excess oxygen can be supplied to the oxide semiconductor layer 106. Further, since oxygen is introduced through the gate insulating layer 110, damage on the oxide semiconductor layer 106 can be favorably suppressed.

By removing hydrogen or moisture from the oxide semiconductor layer 106 to highly purify the oxide semiconductor so as not to contain impurities as much as possible, and supplying oxygen for repairing oxygen vacancies, the oxide semiconductor layer 106 can be turned into an i-type (intrinsic) oxide semiconductor layer or a substantially i-type (intrinsic) oxide semiconductor. This enables the Fermi level (E_{f}) of the oxide semiconductor layer 106 to be at the same level as the intrinsic Fermi level (Eᵢ). Thus, by using the oxide semiconductor layer 106 for the transistor, it is possible to reduce a variation in the threshold voltage (Vth) of the transistor due to oxygen vacancies and a shift of the threshold voltage (AVth).

Next, the gate electrode layer 112 is formed over the gate insulating layer 110 which overlaps with the thin region of the oxide semiconductor layer 106. A metal film is formed over the gate insulating layer 110 and is patterned and etched into a desired shape, whereby the gate electrode layer 112 can be formed (see FIG. 3B).

The gate electrode layer 112 may be formed to have a single-layer structure or a stacked-layer structure using a metal material such as molybdenum, titanium, tantalum, tungsten, aluminum, copper, chrome, neodymium, or scandium, or an alloy material containing any of these materials as its main component by a plasma CVD method, a sputtering method, or the like.

Next, a dopant 128 is selectively introduced into the oxide semiconductor layer 106 using the gate electrode layer 112 as a mask, so that the source region 114a, the drain region 114b, and the pair of low-resistance regions 116 are formed. The dopant 128 is introduced through the gate insulating layer 110 and the metal layers 108a and 108b.

Since the gate insulating layer 110 and the metal layers 108a and 108b are thin in this embodiment, the dopant 128 passes through the gate insulating layer 110 and the metal layers 108a and 108b and is introduced into the oxide semiconductor layer 106, whereby the source region 114a, the drain region 114b, and the pair of low-resistance regions 116 are formed. Note that a region sandwiched between the pair of low-resistance regions 116 becomes the channel formation region 118 into which the dopant 128 is not introduced because the gate electrode layer 112 serves as a mask. In this manner, the dopant 128 is introduced into the oxide semiconductor layer 106 using the gate electrode layer 112 as a mask, whereby the pair of low-resistance regions 116, the source region 114a, and the drain region 114b are formed in a self-aligned manner. Note that in FIG. 3C, since there is no clear interface between the pair of low-resistance regions 116 and the source and drain regions 114a and 114b, they are indicated by the same hatching pattern.

The dopant 128 is an impurity to reduce the resistance of the oxide semiconductor layer 106. As the dopant 128, any one or more of phosphorus (P), arsenic (As), antimony (Sb), boron (B), aluminum (Al), nitrogen (N), argon (Ar), helium (He), neon (Ne), indium (In), fluorine (F), chlorine (Cl), titanium (Ti), and zinc (Zn) can be used. Specifically, when the oxide semiconductor layer 106 contains gallium (Ga) as a composition element, boron (B) is preferably used. Since boron (B) is an element belonging to the same group (Group 13 element) as gallium (Ga), which is the element included in the oxide semiconductor layer 106, boron can exist stably in the oxide semiconductor layer 106.

The dopant 128 is introduced into the oxide semiconductor layer 106 through the gate insulating layer 110 and the metal layers 108a and 108b, by an implantation method. As a method for introducing the dopant 128, an ion implantation method, an ion doping method, a plasma immersion ion implantation method, or the like can be used. In that case, it is preferable to use a single ion of the dopant 128 or a hydride ion, a fluoride ion, or a chloride ion.

The process of introducing the dopant 128 may be controlled by appropriately setting an implantation condition such as acceleration voltage or a dose, or the thicknesses of the gate insulating layer 110 and the metal layers 108a and 108b through which the dopant 128 passes. For example, in the case where boron (B) is used and ions of boron (B) are introduced by an ion implantation method, the acceleration voltage can be 15 kV, and the dose can be greater than or equal to 1×10¹³ ions/cm² and less than or equal to 5×10¹⁶ ions/cm².

The concentration of the dopant 128 in the low-resistance regions 116 and the source and drain regions 114a and 114b is preferably greater than or equal to 5×10¹⁸ ions/cm³ and less than or equal to 1×10²² ions/cm³. The dopant 128 may be introduced with the substrate 102 heated.

The process of introducing the dopant 128 into the oxide semiconductor layer 106 may be performed plural times, and the number of kinds of dopant may be plural.

Further, after the dopant 128 is introduced, heat treatment may be performed. The heat treatment is preferably performed in an oxygen atmosphere for one hour at higher than or equal to 300° C. and lower than or equal to 700° C., preferably higher than or equal to 300° C. and lower than or equal to 450° C. Alternatively, the heat treatment may be performed in a nitrogen atmosphere, a reduced pressure, or the air (ultra-dry air).

In the case where the oxide semiconductor layer 106 is a crystalline oxide semiconductor, the oxide semiconductor layer 106 can partly become amorphous by introducing the dopant 128. In that case, the crystallinity of the oxide semiconductor layer 106 can be recovered by performing heat treatment on the oxide semiconductor layer 106 after the dopant 128 is introduced.

By the heat treatment, the oxide semiconductor layer 106 and the metal layers 108a and 108b are heated in a state where the oxide semiconductor layer 106 is in contact with the metal layers 108a and 108b, so that the metal layers 108a and 108b are reacted with and/or diffused into the oxide semiconductor layer 106 and thus the resistance of the source and drain regions 114a and 114b can be further reduced.

In such a manner, the pair of low-resistance regions 116 is formed so as to sandwich the channel formation region 118 in the thin region of the oxide semiconductor layer 106. The source region 114a and the drain region 114b can be formed in the thick region of the oxide semiconductor layer 106.

Since boron (B) is used as the dopant 128 in this embodiment, boron (B) is included in the low-resistance regions 116 and the source and drain regions 114a and 114b.

Through the above steps, the transistor 140 of this embodiment is manufactured (see FIG. 3C).

Since the transistor 140 includes the oxide semiconductor layer 106 in which the pair of low-resistance regions 116 and the source and drain regions 114a and 114b are provided with the channel formation region 118 sandwiched between the pair of low-resistance regions 116, in a channel length direction, ON characteristics (e.g., the on-state current, the field effect mobility) of the transistor 140 is high and the transistor 140 is capable of high-speed operation and high-speed response. The thickness of the oxide semiconductor layer 106 is different between the region where the gate electrode layer 112 is overlapped and the region where the source and drain regions 114a and 114b are formed. The oxide semiconductor layer 106 is thinner in the region where the gate electrode layer 112 is overlapped than in the regions where the source and drain regions 114a and 114b are formed. Further, the channel formation region 118 is formed in the thin region of the oxide semiconductor layer 106. Since the region of the oxide semiconductor layer 106 where the channel formation region 118 is formed is made thin, the threshold voltage (Vth) can be adjusted in the positive direction.

Then, the protective layer 120 is formed over the gate insulating layer 110 and the gate electrode layer 112. Then, openings reaching the source and drain regions 114a and 114b are formed in the protective layer 120, and the wiring layers 122a and 122b which are electrically connected to the source region 114a and the drain region 114b, respectively, are formed in the openings (see FIG. 3D).

A planarization insulating film may be formed as the protective layer 120 in order to reduce surface unevenness due to the transistor. For the planarization insulating film, an organic material such as polyimide, an acrylic resin, a benzocyclobutene-based resin can be used. In addition to such organic materials, it is also possible to use a low-dielectric constant material (a low-k material) or an inorganic material such as silicon oxide, silicon oxynitride, silicon nitride, hafnium oxide, aluminum oxide. Note that the planarization insulating film may be formed by stacking a plurality of insulating films formed from these materials.

In a transistor including the oxide semiconductor layer described in this embodiment, impurities such as hydrogen and water are sufficiently removed in the oxide semiconductor layer which is highly purified and compensated for oxygen vacancies, and the concentration of hydrogen in the oxide semiconductor layer is 5×10¹⁹/cm³ or less, preferably 5×10¹⁸/cm³ or less. Note that the hydrogen concentration of the oxide semiconductor layer was measured by SIMS (secondary ion mass spectrometry).

The number of carriers in the oxide semiconductor layer is extremely small (close to zero), and the carrier concentration is less than 1×10¹⁴/cm³, preferably less than 1×10¹²/cm³, further preferably less than 1×10¹¹/cm³.

In the transistor formed according to this embodiment using the highly purified oxide semiconductor layer containing excess oxygen with which an oxygen vacancy is filled, the value of a current in the off state (the value of an off-state current) per unit channel width (1 μm) can be reduced so as to be less than or equal to 100 zA/μm (1 zA (zeptoampere) is 1×10⁻²¹ A), preferably less than or equal to 10 zA/μm, more preferably less than or equal to 1 zA/μm, further preferably less than or equal to 100 yA/μm at room temperature.

Since the transistor manufactured according to this embodiment includes an oxide semiconductor layer in which the pair of low-resistance regions and the source and drain regions are provided with the channel formation region sandwiched between the pair of low-resistance regions, in a channel length direction, ON characteristics (e.g., the on-state current, the field effect mobility) of the transistor is high and the transistor is capable of high-speed operation and high-speed response. The thickness of the oxide semiconductor layer is different between the region where the gate electrode layer is overlapped and the region where the source and drain regions are formed. The oxide semiconductor layer is thinner in the region where the gate electrode layer is overlapped than in the regions where the source and drain regions are formed. Further, the channel formation region is formed in the thin region of the oxide semiconductor layer. Since the region of the oxide semiconductor layer where the channel formation region is formed is made thin, the threshold voltage (Vth) can be adjusted in the positive direction while a short-channel effect is suppressed. Thus, a normally-off semiconductor device can be obtained.

In addition, the channel formation region is provided between a pair of low-resistance regions; thus, an electric field applied to the channel formation region can be relieved. Further, the source and drain regions are directly formed in the oxide semiconductor layer and in contact with the channel formation region through the low-resistance regions; thus, the contact resistance between the channel formation region and the source and drain regions can be reduced.

This embodiment can be combined with any of the other embodiments as appropriate.

### Embodiment 3

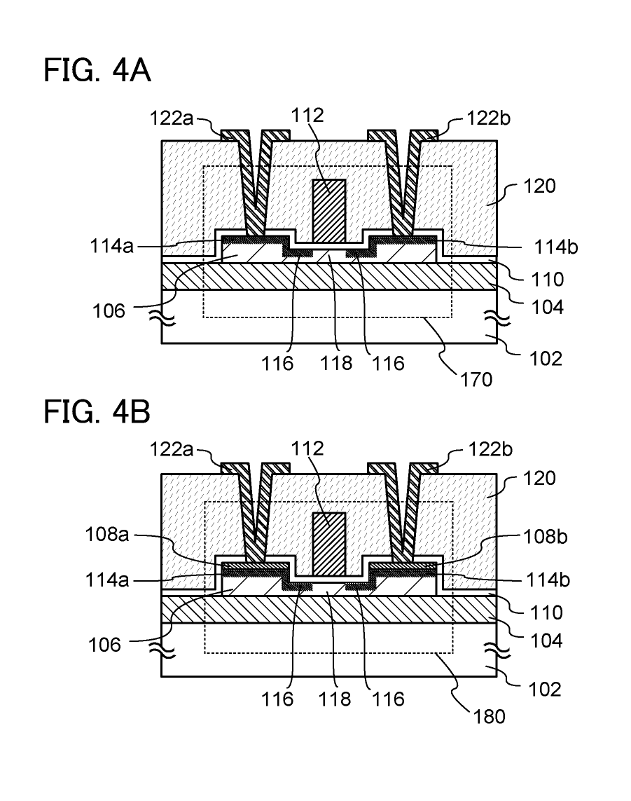

In this embodiment, a mode different from the transistors 140 to 160 described with reference to FIGS. 1A to 1C in Embodiment 1 is described with reference to FIGS. 4A and 4B. In this embodiment, an example of the semiconductor device is described with reference to cross-sectional views of a transistor including an oxide semiconductor layer. Note that portions similar to those in FIGS. 1A to 1C are denoted by the same reference numerals, and description thereof is skipped.

FIGS. 4A and 4B are cross-sectional views of transistors 170 and 180, respectively. Note that the transistors 170 and 180 are top-gate top-contact transistors (so called TGTC transistor), which can be seen from a position of a gate electrode layer with respect to a semiconductor layer (an oxide semiconductor layer in this specification), positions of source and drain regions to the semiconductor layer, and positions of the wiring layers, which are in contact with the source and drain regions, with respect to the source and drain regions. Structures of the transistors are described below.

The transistor 170 in FIG. 4A includes a substrate 102; an oxide insulating layer 104 over the substrate 102; an oxide semiconductor layer 106 formed over the oxide insulating layer 104 and including a channel formation region 118, low-resistance regions 116, a source region 114a, and a drain region 114b; a gate insulating layer 110 over the oxide insulating layer 104 and the oxide semiconductor layer 106; and a gate electrode layer 112 over the gate insulating layer 110.

Note that in the oxide semiconductor layer 106, the region overlapping with the gate electrode layer 112 is thinner than the regions where the source region 114a and the drain region 114b are formed. The oxide semiconductor layer 106 includes the pair of low-resistance regions 116, the channel formation region 118 sandwiched between the pair of low-resistance regions 116, and the source region 114a and the drain region 114b which are in contact with the pair of low-resistance regions. The pair of low-resistance regions 116 is formed in the thin region of the oxide semiconductor layer 106. The source region 114a and the drain region 114b are formed in the thick regions of the oxide semiconductor layer 106.

The thin region of the oxide semiconductor layer 106 can be formed by an etching process. For example, an oxide semiconductor layer is formed with a thickness of 15 nm to 30 nm and is then etched to have about 5 nm. Since the channel formation region 118 is formed in the oxide semiconductor layer 106 with such a thickness, a short-channel effect due to miniaturization of the transistor can be reduced. The thin region of the oxide semiconductor layer 106 can be formed by etching process. The channel formation region 118 can be formed in the thin region, and the source and drain regions 114a and 114b can be formed in the thick regions. With such a structure, the contact resistance between the channel formation region 118 and the source and drain regions 114a and 114b can be reduced as the thickness of the oxide semiconductor layer 106 decreases.

Further, the pair of low-resistance regions 116, the source region 114a, and the drain region 114b which are included in the oxide semiconductor layer 106 have a resistance lower than the channel formation region 118 and include, for example, phosphorus (P) or boron (B). For example, the gate electrode layer 112 is formed and then a dopant containing phosphorus (P) or boron (B) is introduced into the oxide semiconductor layer 106 (impurity introduction), so that these low-resistance regions can be formed in a self-aligned manner.

In addition, since the pair of low-resistance regions 116 is provided between the channel formation region 118 and the source and drain regions 114a and 114b, a negative shift of the threshold voltage due to a short-channel effect can be reduced.

Further, the transistor 170 may include a protective layer 120 over the gate insulating layer 110 and the gate electrode layer 112; and wirings 122a and 122b, respectively in contact with the source region 114a and the drain region 114b, through openings formed in the protective layer 120 and the gate insulating layer 110. Since the protective layer 120 and the wiring layers 122a and 122b are formed over the transistor 170, the transistors 170 can be integrated. The protective layer 120 is preferably provided, in which case, unevenness of the transistor 170 can be suppressed or entry of impurities (e.g., water) into the transistor 170 can be suppressed.

The difference between the transistor 170 and the transistor 140 in FIG. 1A which is described in Embodiment 1 is whether or not the metal layers 108a and 108b over the source and drain regions 114a and 114b are provided. As in the transistor 170 in this embodiment, the metal layers 108a and 108b are not necessarily provided.

Next, a transistor 180 in FIG. 4B is described.

The transistor 180 in FIG. 4B includes a substrate 102; an oxide insulating layer 104 over the substrate 102; an oxide semiconductor layer 106 formed over the oxide insulating layer 104 and including a channel formation region 118, low-resistance regions 116, a source region 114a, and a drain region 114b; metal layers 108a and 108b in contact with the source region 114a and the drain region 114b, respectively; a gate insulating layer 110 over the oxide insulating layer 104, the oxide semiconductor layer 106, and the metal layers 108a and 108b; and a gate electrode layer 112 over the gate insulating layer 110.

Note that in the oxide semiconductor layer 106, the region overlapping with the gate electrode layer 112 is thinner than the regions where the source region 114a and the drain region 114b are formed. The oxide semiconductor layer 106 includes the pair of low-resistance regions 116, the channel formation region 118 sandwiched between the pair of low-resistance regions 116, and the source region 114a and the drain region 114b which are in contact with the pair of low-resistance regions. The pair of low-resistance regions 116 is formed in the thin region of the oxide semiconductor layer 106. The source region 114a and the drain region 114b are formed in the thick regions of the oxide semiconductor layer 106 to be in contact with the metal layers 108a and 108b, respectively.

The thin region of the oxide semiconductor layer 106 can be formed by an etching process. For example, an oxide semiconductor layer is formed with a thickness of 15 nm to 30 nm and is then etched to have about 5 nm. Since the channel formation region 118 is formed in the oxide semiconductor layer 106 with such a thickness, a short-channel effect due to miniaturization of the transistor can be reduced. The thin region of the oxide semiconductor layer 106 can be formed by etching process. The channel formation region 118 can be formed in the thin region, and the source and drain regions 114a and 114b can be formed in the thick regions. With such a structure, the contact resistance between the channel formation region 118 and the source and drain regions 114a and 114b, which increases as the thickness of the oxide semiconductor layer 106 decreases, can be reduced.

Further, the pair of low-resistance regions 116, the source region 114a, and the drain region 114b which are included in the oxide semiconductor layer 106 have a resistance lower than the channel formation region 118 and include, for example, phosphorus (P) or boron (B). For example, the gate electrode layer 112 is formed and then a dopant containing phosphorus (P) or boron (B) is introduced into the oxide semiconductor layer 106 (impurity introduction), so that these low-resistance regions can be formed in a self-aligned manner.

In addition, since the pair of low-resistance regions 116 is provided between the channel formation region 118 and the source and drain regions 114a and 114b, a negative shift of the threshold voltage due to a short-channel effect can be reduced.

The source region 114a and the drain region 114b can be formed as follows: heat treatment or the like is performed in a state where the oxide semiconductor layer 106 is in contact with the metal layers 108a and 108b, whereby the metal layers 108a and 108b are reacted with and/or diffused into the oxide semiconductor layer 106. A further reduction in the resistance of the source region 114a and the drain region 114b can be achieved owing to the provision of the metal layers 108a and 108b in addition to the impurity introduction.

Further, the transistor 180 may include the protective layer 120 over the gate insulating layer 110 and the gate electrode layer 112; and the wiring layers 122a and 122b, respectively in contact with the metal layers 108a and 108b, through openings formed in the protective layer 120 and the gate insulating layer 110. Note that the wiring layer 122a is electrically connected to the source region 114a through the metal layer 108a, and the wiring layer 122b is electrically connected to the drain region 114b through the metal layer 108b.

Since the protective layer 120 and the wiring layers 122a and 122b are formed over the transistor 180, the transistors 180 can be integrated. The protective layer 120 is preferably provided, in which case, unevenness of the transistor 180 can be suppressed or entry of impurities (e.g., water) into the transistor 180 can be suppressed.

Note that a difference between the transistor 180 and the transistor 140 in FIG. 1A described in Embodiment 1 is the regions with which the wiring layers 122a and 122b are in contact. In the transistor 140, the wiring layers 122a and 122b are directly in contact with the source and drain regions 114a and 114b, whereas in the transistor 180, they are connected to the source and drain regions 114a and 114b through the metal layers 108a and 108b. As in these cases, the wiring layers 122a and 122b are at least be electrically connected to the source and drain regions 114a and 114b, respectively.

As described above, the semiconductor devices in FIGS. 4A and 4B have in common that the semiconductor layer is formed using an oxide semiconductor layer, and that the oxide semiconductor layer at least serving as a channel formation region is partly etched and thinned in order to adjust the thickness of the channel formation region. Since the region of the oxide semiconductor layer where the channel formation region is included is thin, the threshold voltage (Vth) can be adjusted in the positive direction while a short-channel effect is suppressed. Thus, a normally-off semiconductor device can be obtained.

In the semiconductor device in FIGS. 4A and 4B, a dopant containing phosphorus (P) or boron (B) is introduced into a thick region of the oxide semiconductor layer to form a source region and a drain region in the oxide semiconductor layer, so that the contact resistance between the source and drain regions and the channel formation region which are connected to each other can be reduced. Thus, the semiconductor device with a high on-state current can be obtained.

This embodiment can be combined with any of the other embodiments as appropriate.

### Embodiment 4

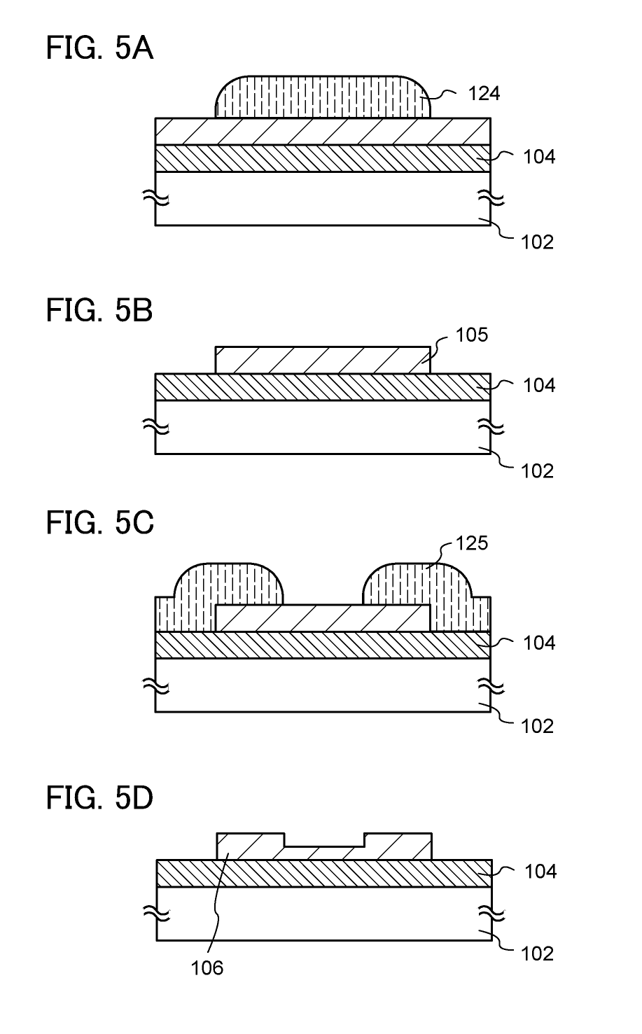

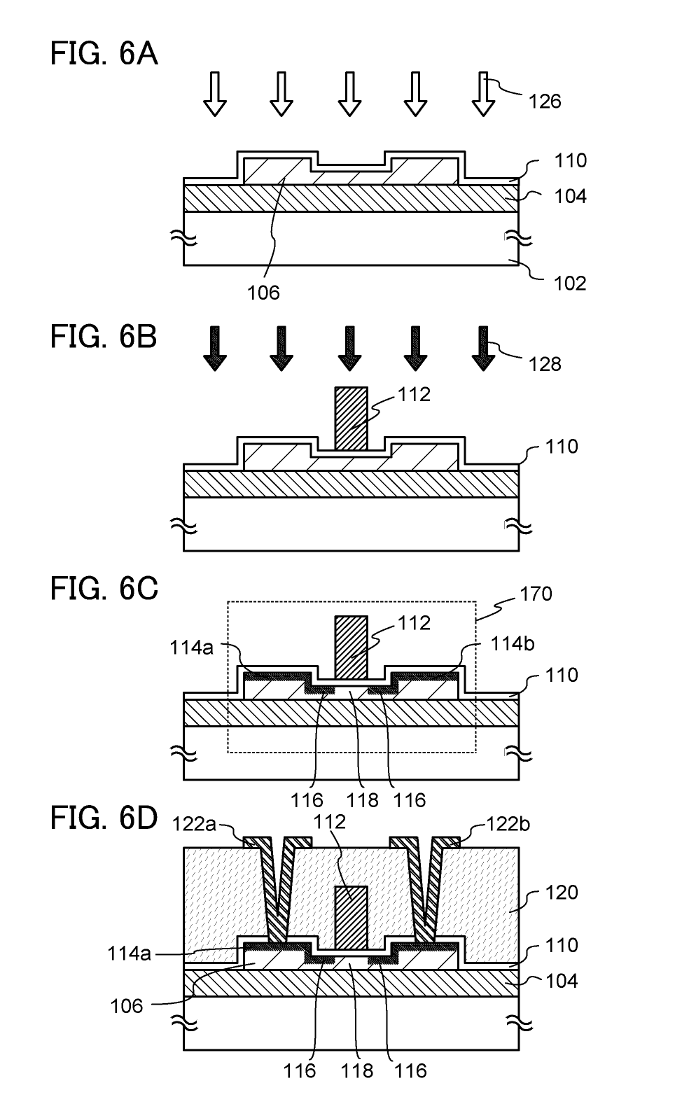

In this embodiment, a method for manufacturing the transistor 170 described in Embodiment 3 with reference to FIG. 4A is specifically described with reference to FIGS. 5A to 5D and FIGS. 6A to 6D. Note that portions similar to those in FIG. 4A are denoted by the same reference numerals, and description thereof is skipped.

First, the oxide insulating layer 104 is formed over the substrate 102 and then, an oxide semiconductor film is formed over the oxide insulating layer 104. Then, a resist mask 124 is formed over a desired region of the oxide semiconductor film (see FIG. 5A).

Materials and manufacturing methods of the substrate 102, the oxide insulating layer 104, the oxide semiconductor film, and the resist mask 124 are similar to those in Embodiment 2; thus, description thereof in Embodiment 2 can be referred to.

Unnecessary regions of the oxide semiconductor film are removed by an etching process with the use of the resist mask 124 as a mask and then, the resist mask 124 is removed; thus, the island-shaped oxide semiconductor layer 105 is formed (see FIG. 5B).

Note that the etching of the oxide semiconductor film may be dry etching, wet etching, or both dry etching and wet etching. As an etchant used for wet etching of the oxide semiconductor film, for example, a mixed solution of phosphoric acid, acetic acid, and nitric acid, or the like can be used. In addition, ITO07N (produced by KANTO CHEMICAL CO., INC.) may also be used.

Next, the resist mask 125 is formed over the oxide insulating layer 104 and the oxide semiconductor layer 105 (see FIG. 5C).

The resist mask 125 can be formed using a method and a material similar to those described in Embodiment 2; thus, description thereof can be referred to.

Unnecessary regions of the oxide semiconductor layer 105 are removed by an etching process with the use of the resist mask 125 as a mask, and then, the resist mask 125 is removed. The oxide semiconductor layer 105 becomes an oxide semiconductor layer 106 with a thin region, through the etching process (see FIG. 5D).

Note that part of the thin region of the oxide semiconductor layer 106 becomes a channel formation region, and the thick regions of the oxide semiconductor layer 106 serve as a source region and a drain region. The thin region of the oxide semiconductor layer 106 needs to be thinner than at least the thick regions of the oxide semiconductor layer 106, and preferably has a thickness of greater than or equal to 1 nm and less than or equal to 10 nm, further preferably greater than or equal to 3 nm and less than or equal to 5 nm. Note that the thickness of the thin region of the oxide semiconductor layer 106 is not limited thereto and can be set as appropriate depending on a composition element and a deposition method of the oxide semiconductor or the size of a transistor (e.g., L/W size or L/W size).

The thickness of the gate insulating layer 110 is preferably greater than or equal to 1 nm and less than or equal to 100 nm, further preferably greater than or equal to 1 nm and less than or equal to 30 nm. With the gate insulating layer 110 thinned, a short-channel effect can be suppressed. In this embodiment, as the gate insulating layer 110, a 15-nm-thick silicon oxide film is formed by a plasma CVD method.

The oxygen 126 is introduced into the oxide semiconductor layer 106 through the gate insulating layer 110 (see FIG. 6A).

The oxygen 126 (containing at least any of an oxygen radical, an oxygen atom, and an oxygen ion) is introduced into the oxide semiconductor layer 106 (oxygen introduction). Oxygen can be introduced by an ion implantation method, an ion doping method, a plasma immersion ion implantation method, plasma treatment, or the like.

For supply of oxygen to the oxide semiconductor layer, oxygen contained in the gate insulating layer 110 may be supplied to the oxide semiconductor layer 106; however, the amount of oxygen contained in the thin gate insulating layer 110 (15 nm) in this embodiment is smaller than in the case where the gate insulating layer is thick (e.g., 100 nm or more). Thus, there is a possibility that oxygen is not sufficiently supplied to the oxide semiconductor layer 106. For this reason, the oxygen introduction is performed as described in this embodiment so that excess oxygen can be supplied to the oxide semiconductor layer 106. Further, since oxygen is introduced through the gate insulating layer 110, damage on the oxide semiconductor layer 106 can be favorably suppressed.

By removing hydrogen or moisture from the oxide semiconductor layer 106 to highly purify the oxide semiconductor so as not to contain impurities as much as possible, and supplying oxygen for repairing oxygen vacancies, the oxide semiconductor layer 106 can be turned into an i-type (intrinsic) oxide semiconductor layer or a substantially i-type (intrinsic) oxide semiconductor. This enables the Fermi level (E_{f}) of the oxide semiconductor layer 106 to be at the same level as the intrinsic Fermi level (Eᵢ). Thus, by using the oxide semiconductor layer 106 for the transistor, it is possible to reduce a variation in the threshold voltage (Vth) of the transistor due to oxygen vacancies and a shift of the threshold voltage (ΔVth).

Next, the gate electrode layer 112 is formed over the gate insulating layer 110 which overlaps with the thin region of the oxide semiconductor layer 106. A metal film is formed over the gate insulating layer 110 and is patterned and etched into a desired shape, whereby the gate electrode layer 112 can be formed (see FIG. 6B).

The gate electrode layer 112 may be formed to have a single-layer structure or a stacked-layer structure using a metal material such as molybdenum, titanium, tantalum, tungsten, aluminum, copper, chrome, neodymium, or scandium, or an alloy material containing any of these materials as its main component by a plasma CVD method, a sputtering method, or the like.

Next, a dopant 128 is selectively introduced into the oxide semiconductor layer 106 using the gate electrode layer 112 as a mask, so that the source region 114a, the drain region 114b, and the pair of low-resistance regions 116 are formed. The dopant 128 is introduced through the gate insulating layer 110.

Since the gate insulating layer 110 is thin in this embodiment, the dopant 128 passes through the gate insulating layer 110 and is introduced into the oxide semiconductor layer 106, whereby the source region 114a, the drain region 114b, and the pair of low-resistance regions 116 are formed. Note that a region sandwiched between the pair of low-resistance regions 116 becomes the channel formation region 118 into which the dopant 128 is not introduced because the gate electrode layer 112 serves as a mask. In this manner, the dopant 128 is introduced into the oxide semiconductor layer 106 using the gate electrode layer 112 as a mask, whereby the pair of low-resistance regions 116, the source region 114a, and the drain region 114b are formed in a self-aligned manner. Note that in FIG. 6C, since there is no clear interface between the pair of low-resistance regions 116 and the source and drain regions 114a and 114b, they are indicated by the same hatching pattern.

The dopant 128 is an impurity to reduce the resistance of the oxide semiconductor layer 106. As the dopant 128, any one or more of phosphorus (P), arsenic (As), antimony (Sb), boron (B), aluminum (Al), nitrogen (N), argon (Ar), helium (He), neon (Ne), indium (In), fluorine (F), chlorine (Cl), titanium (Ti), and zinc (Zn) can be used. Specifically, when the oxide semiconductor layer 106 contains gallium (Ga) as a composition element, boron (B) is preferably used. Since boron (B) is an element belonging to the same group (Group 13 element) as gallium (Ga), which is the element included in the oxide semiconductor layer 106, boron can exist stably in the oxide semiconductor layer 106.

The dopant 128 is introduced into the oxide semiconductor layer 106 through the gate insulating layer 110, by an implantation method. As a method for introducing the dopant 128, an ion implantation method, an ion doping method, a plasma immersion ion implantation method, or the like can be used. In that case, it is preferable to use a single ion of the dopant 128, a hydride ion or a fluoride ion, or a chloride ion.

The process of introducing the dopant 128 may be controlled by appropriately setting an implantation condition such as acceleration voltage or a dose, or the thicknesses of the gate insulating layer 110 through which the dopant 128 passes. For example, in the case where boron (B) is used and ions of boron (B) are introduced by an ion implantation method, the acceleration voltage can be 15 kV, and the dose can be greater than or equal to 1×10¹³ ions/cm² and less than or equal to 5×10¹⁶ ions/cm².

The concentration of the dopant 128 in the low-resistance regions 116 and the source and drain regions 114a and 114b is preferably greater than or equal to 5×10¹⁸ ions/cm³ and less than or equal to 1×10²² ions/cm³. The dopant 128 may be introduced with the substrate 102 heated.

The process of introducing the dopant 128 into the oxide semiconductor layer 106 may be performed plural times, and the number of kinds of dopant may be plural.

Further, after the dopant 128 is introduced, heat treatment may be performed. The heat treatment is preferably performed in an oxygen atmosphere for one hour at higher than or equal to 300° C. and lower than or equal to 700° C., preferably higher than or equal to 300° C. and lower than or equal to 450° C. Alternatively, the heat treatment may be performed in a nitrogen atmosphere, a reduced pressure, or the air (ultra-dry air).

In the case where the oxide semiconductor layer 106 is a crystalline oxide semiconductor, the oxide semiconductor layer 106 can partly become amorphous by introducing the dopant 128. In that case, the crystallinity of the oxide semiconductor layer 106 can be recovered by performing heat treatment on the oxide semiconductor layer 106 after the dopant 128 is introduced.

In such a manner, the pair of low-resistance regions 116 is formed so as to sandwich the channel formation region 118 in the thin region of the oxide semiconductor layer 106. The source region 114a and the drain region 114b can be formed in the thick region of the oxide semiconductor layer 106.

Since boron (B) is used as the dopant 128 in this embodiment, boron (B) is included in the low-resistance regions 116 and the source and drain regions 114a and 114b.

Through the above steps, the transistor 170 of this embodiment is manufactured (see FIG. 6C).

Since the transistor 170 includes the oxide semiconductor layer 106 in which the pair of low-resistance regions 116 and the source and drain regions 114a and 114b are provided with the channel formation region 118 sandwiched between the pair of low-resistance regions 116, in a channel length direction, ON characteristics (e.g., the on-state current, the field effect mobility) of the transistor 170 is high and the transistor 170 is capable of high-speed operation and high-speed response. The thickness of the oxide semiconductor layer 106 is different between the region where the gate electrode layer 112 is overlapped and the region where the source and drain regions 114a and 114b are formed. The oxide semiconductor layer 106 is thinner in the region where the gate electrode layer 112 is overlapped than in the regions where the source and drain regions 114a and 114b are formed. Further, the channel formation region 118 is formed in the thin region of the oxide semiconductor layer 106. Since the region of the oxide semiconductor layer 106 where the channel formation region 118 is formed is made thin, the threshold voltage (Vth) can be adjusted in the positive direction.

Then, the protective layer 120 is formed over the gate insulating layer 110 and the gate electrode layer 112. Then, openings reaching the source and drain regions 114a and 114b are formed in the protective layer 120, and the wiring layers 122a and 122b which are electrically connected to the source region 114a and the drain region 114b, respectively, are formed in the openings (see FIG. 6D).

A planarization insulating film may be formed as the protective film 120 in order to reduce surface unevenness due to the transistor. For the planarization insulating film, an organic material such as polyimide, an acrylic resin, a benzocyclobutene-based resin can be used. In addition to such organic materials, it is also possible to use a low-dielectric constant material (a low-k material) or an inorganic material such as silicon oxide, silicon oxynitride, silicon nitride, hafnium oxide, aluminum oxide. Note that the planarization insulating film may be formed by stacking a plurality of insulating films formed from these materials.

In a transistor including the oxide semiconductor layer described in this embodiment, impurities such as hydrogen and water are sufficiently removed in the oxide semiconductor layer which is highly purified and compensated for oxygen vacancies, and the concentration of hydrogen in the oxide semiconductor layer is 5×10¹⁹/cm³ or less, preferably 5×10¹⁸/cm³ or less. Note that the hydrogen concentration of the oxide semiconductor layer was measured by SIMS (secondary ion mass spectrometry).

The number of carriers in the oxide semiconductor layer is extremely small (close to zero), and the carrier concentration is less than 1×10¹⁴/cm³, preferably less than 1×10¹²/cm³, further preferably less than 1×10¹¹/cm³.

In the transistor formed according to this embodiment using the highly purified oxide semiconductor layer containing excess oxygen with which an oxygen vacancy is filled, the value of a current in the off state (the value of an off-state current) per unit channel width (1 μm) can be reduced so as to be less than or equal to 100 zA/μm (1 zA (zeptoampere) is 1×10⁻²¹ A), preferably less than or equal to 10 zA/μm, more preferably less than or equal to 1 zA/μm, further preferably less than or equal to 100 yA/μm at room temperature.

Since the transistor manufactured according to this embodiment includes the oxide semiconductor layer in which the pair of low-resistance regions and the source and drain regions are provided with the channel formation region sandwiched between the pair of low-resistance regions, in a channel length direction, ON characteristics (e.g., the on-state current, the field effect mobility) of the transistor is high and the transistor is capable of high-speed operation and high-speed response. The thickness of the oxide semiconductor layer is different between the region where the gate electrode layer is overlapped and the region where the source and drain regions are formed. The oxide semiconductor layer is thinner in the region where the gate electrode layer is overlapped than in the regions where the source and drain regions are formed. Further, the channel formation region is formed in the thin region of the oxide semiconductor layer. Since the region of the oxide semiconductor layer where the channel formation region is formed is made thin, the threshold voltage (Vth) can be adjusted in the positive direction. Thus, a normally-off semiconductor device can be obtained.

In addition, the channel formation region is provided between the pair of low-resistance regions; thus, an electric field applied to the channel formation region can be relieved. Further, the source and drain regions are directly formed in the oxide semiconductor layer and in contact with the channel formation region through the low-resistance regions; thus, the contact resistance between the channel formation region and the source and drain regions can be reduced.

This embodiment can be combined with any of the other embodiments as appropriate.

### Embodiment 5

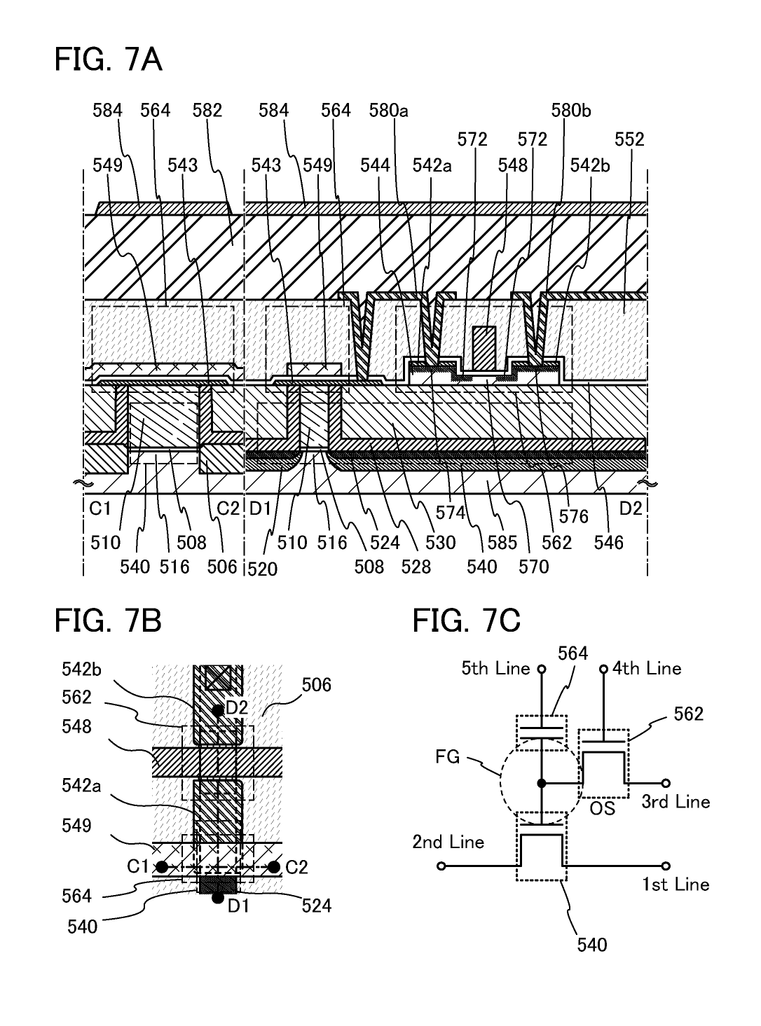

The transistor the example of which is described in any of Embodiments 1 to 4 can be favorably used for a semiconductor device including an integrated circuit in which a plurality of transistors is stacked. In this embodiment, as an example of the semiconductor device, a memory medium (memory element) is described with reference to FIGS. 7A to 7C.

In this embodiment, a semiconductor device including a first transistor 540 which is formed using a single crystal semiconductor substrate and a second transistor 562 which is formed using an oxide semiconductor film and is provided above the first transistor 540 with an insulating film positioned between the first transistor 540 and the second transistor 562 is manufactured. The transistor the example of which is described in any of Embodiment 1 to 4 can be preferably used as the transistor 562. In this embodiment, an example in which a transistor having a structure similar to that of the transistor 140 described in Embodiment 1 is used as the transistor 562 is described.

Semiconductor materials and structures of the transistor 540 and the transistor 562, which are stacked, may be the same as or different from each other. This embodiment describes an example in which a transistor with a suitable material and structure is used in each circuit of a memory medium (memory element).

FIGS. 7A to 7C illustrate an example of a structure of a semiconductor device. FIG. 7A illustrates a cross section of the semiconductor device, and FIG. 7B illustrates a plan view of the semiconductor device. Here, FIG. 7A corresponds to a cross section along line C1-C2 and line D1-D2 in FIG. 7B. FIG. 7C is an example of a diagram of a circuit using the semiconductor device as a memory element. The semiconductor device illustrated in FIGS. 7A and 7B includes the transistor 540 formed using a first semiconductor material in a lower portion, and the transistor 562 formed using a second semiconductor material in an upper portion. In this embodiment, the first semiconductor material is a semiconductor material other than an oxide semiconductor, and the second semiconductor material is an oxide semiconductor. As the semiconductor material other than an oxide semiconductor, for example, silicon, germanium, silicon germanium, silicon carbide, gallium arsenide, or the like can be used, and a single crystal semiconductor is preferably used. Alternatively, an organic semiconductor material or the like may be used. A transistor including such a semiconductor material other than an oxide semiconductor can operate at high speed easily. On the other hand, a transistor using an oxide semiconductor enables charge to be held for a long time owing to its characteristics.

A method for manufacturing the semiconductor device in FIGS. 7A to 7C is described below.

The transistor 540 includes a channel formation region 516 provided in a substrate 585 containing a semiconductor material (e.g., silicon), impurity regions 520 provided so that the channel formation region 516 is interposed therebetween, metal compound regions 524 in contact with the impurity regions 520, a gate insulating film 508 provided over the channel formation region 516, and a gate electrode layer 510 provided over the gate insulating film 508.

As the substrate 585 containing a semiconductor material, a single crystal semiconductor substrate or a polycrystalline semiconductor substrate of silicon, silicon carbide, or the like; a compound semiconductor substrate of silicon germanium or the like; an SOI substrate; or the like can be used. Note that although the term “SOI substrate” generally means a substrate in which a silicon semiconductor film is provided over an insulating surface, the term “SOI substrate” in this specification and the like also includes a substrate in which a semiconductor film formed using a material other than silicon is provided over an insulating surface. That is, a semiconductor film included in the “SOI substrate” is not limited to a silicon semiconductor film. Moreover, the SOI substrate can be a substrate having a structure where a semiconductor film is provided over an insulating substrate such as a glass substrate with an insulating film positioned therebetween.

As a method of forming the SOI substrate, any of the following methods can be used: a method in which oxygen ions are implanted into a mirror-polished wafer and then heating is performed at a high temperature, whereby an oxide layer is formed at a certain depth from a surface of the wafer and a defect caused in the surface layer is eliminated; a method in which a semiconductor substrate is separated by utilizing a phenomenon in which microvoids formed by hydrogen ion irradiation grow because of heat treatment; a method in which a single crystal semiconductor film is formed over an insulating surface by crystal growth; and the like.

For example, ions are added through one surface of a single crystal semiconductor substrate, an embrittlement layer is formed at a certain depth from the surface of the single crystal semiconductor substrate, and an insulating film is formed over one of the surface of the single crystal semiconductor substrate and an element substrate. Heat treatment is performed in a state where the single crystal semiconductor substrate and the element substrate are bonded to each other with the insulating film interposed therebetween, so that a crack is generated in the embrittlement layer and the single crystal semiconductor substrate is separated along the embrittlement layer. Accordingly, a single crystal semiconductor film, which is separated from the single crystal semiconductor substrate, is formed as a semiconductor film over the element substrate. An SOI substrate formed by the above method can also be favorably used.

An element isolation insulating film 506 is provided on the substrate 585 so as to surround the transistor 540. Note that for high integration, it is preferable that, as in FIG. 7A, the transistor 540 do not include a sidewall insulating film. On the other hand, in the case where the characteristics of the transistor 540 have priority, a sidewall insulating film may be provided on a side surface of the gate electrode layer 510, and the impurity region 520 may include a region having a different impurity concentration.

The transistor 540 formed using a single crystal semiconductor substrate can operate at high speed. Thus, when the transistor is used as a reading transistor, data can be read at high speed. In this embodiment, two insulating films are formed so as to cover the transistor 540. As treatment prior to formation of the transistor 562 and a capacitor 564, CMP treatment is performed on the two insulating films, whereby an insulating layer 528 and an insulating layer 530 which are planarized are formed and, at the same time, an upper surface of the gate electrode layer 510 is exposed.

As the insulating layers 528 and 530, typically, an inorganic insulating film such as a silicon oxide film, a silicon oxynitride film, an aluminum oxide film, an aluminum oxynitride film, a silicon nitride film, an aluminum nitride film, a silicon oxynitride film, or an aluminum oxynitride film can be used. The insulating layers 528 and 530 can be formed by a plasma CVD method, a sputtering method, or the like.

Alternatively, an organic material such as polyimide, an acrylic resin, or a benzocyclobutene resin can be used. Other than such organic materials, it is also possible to use a low-dielectric constant material (low-k material) or the like. In the case of using an organic material, the insulating film 528 and the insulating film 530 may be formed by a wet method such as a spin coating method or a printing method.

Note that in the insulating layer 530, a film to be in contact with the semiconductor layer is formed using a silicon oxide film.

In this embodiment, a 50-nm-thick silicon oxynitride film is formed as the insulating layer 528 by a sputtering method, and a 550-nm-thick silicon oxide film is formed as the insulating layer 530 by a sputtering method.

A semiconductor film is formed over the insulating layer 530 which has been sufficiently planarized by CMP treatment. In this embodiment, as the semiconductor film, an oxide semiconductor film is formed by a sputtering method with the use of an In—Ga—Zn—O-based metal oxide target.

Then, a metal film is formed over the oxide semiconductor film, and the metal film and the oxide semiconductor film are selectively etched, so that an island-shaped oxide semiconductor layer 544 part of which is thinned by etching to serve as at least the channel formation region, metal layers 542a and 542b, and a connection electrode layer 543 are formed.

Next, a gate insulating layer 546 is formed over the insulating layer 530, the oxide semiconductor layer 544, the metal layers 542a and 542b, and the connection electrode layer 543, and a gate electrode layer 548 is formed over the gate insulating layer 546. The gate electrode layer 548 can be formed in such a manner that a conductive film is formed and then etched selectively.

Next, a capacitor wiring layer 549 is formed over the gate insulating layer 546. The capacitor wiring layer 549 can be formed in such a manner that a conductive film is formed and then etched selectively. Note that the capacitor wiring layer 549 may be formed by the steps similar to that of the gate electrode layer 548.

The gate insulating layer 546 can be formed using any of a silicon oxide film, a silicon nitride film, a silicon oxynitride film, a silicon nitride oxide film, an aluminum nitride film, an aluminum oxynitride film, an aluminum nitride oxide film, a hafnium oxide film, a gallium oxide film, and an aluminum oxide film by a plasma CVD method, a sputtering method, or the like.

The conductive film which can be used for the gate electrode layer 510, the gate electrode layer 548, the capacitor wiring layer 549, the metal layers 542a and 542b, and the connection electrode layer 543 can be formed by a PVD method typified by a sputtering method or a CVD method such as a plasma CVD method. As a material of the conductive film, an element selected from Al, Cr, Cu, Ta, Ti, Mo, and W, an alloy including any of these elements as its component, or the like can be used. Any of Mn, Mg, Zr, Be, Nd, and Sc, or a material including any of these in combination may be used.

The conductive layer may have a single-layer structure or a stacked-layer structure of two or more layers. For example, the conductive layer can have a single-layer structure of a titanium film or a titanium nitride film, a single-layer structure of an aluminum film containing silicon, a two-layer structure in which a titanium film is stacked over an aluminum film, a two-layer structure in which a titanium film is stacked over a titanium nitride film, or a three-layer structure in which a titanium film, an aluminum film, and a titanium film are stacked in this order.

Next, a dopant (boron, in this embodiment) is introduced into the oxide semiconductor layer 544 through the gate insulating layer 546 and the metal layers 542a and 542b, with the use of the gate electrode layer 548 as a mask (impurity introduction), and then, heat treatment is performed. Through the above process, a channel formation region 570, a pair of low-resistance regions 572, a source region 574, and a drain region 576 are formed in the oxide semiconductor layer 544 in a self-aligned manner. Note that the regions where the channel formation region 570 and the pair of low-resistance regions 572 are formed are thinner than the regions where the source region 574 and the drain region 576 are formed.

By the heat treatment after the impurity introduction, the oxide semiconductor layer 544 and the metal layers 542a and 542b are heated in a state where the oxide semiconductor layer 544 is in contact with the metal layers 542a and 542b, so that the metal layers 542a and 542b are reacted with and/or diffused into the oxide semiconductor layer 544 and thus the resistance of the source and drain regions 574 and 576 can be further reduced.

Since the transistor 562 includes the oxide semiconductor layer 544 in which the pair of low-resistance regions 572 and the source and drain regions 574 and 576 are provided with the channel formation region 570 sandwiched between the pair of low-resistance regions 572, in a channel length direction, ON characteristics (e.g., the on-state current, the field effect mobility) of the transistor 562 is high and the transistor 562 is capable of high-speed operation and high-speed response. The thickness of the oxide semiconductor layer 544 is different between the region where the gate electrode layer 548 is overlapped and the region where the source region 574 and the drain region 576 are formed. The oxide semiconductor layer 544 is thinner in the region where the gate electrode layer 548 is overlapped than in the regions where the source region 574 and the drain region 576 are formed. Further, the channel formation region 570 is formed in the thin region of the oxide semiconductor layer 544. Since the region of the oxide semiconductor layer 544 where the channel formation region 570 is formed is made thin, the threshold voltage (Vth) can be adjusted in the positive direction.

In addition, the channel formation region 570 is provided between the pair of low-resistance regions 572; thus, an electric field applied to the channel formation region 570 can be relieved. Further, the source region 574 and the drain region 576 are directly formed in the oxide semiconductor layer 544 and in contact with the channel formation region 570 through the low-resistance regions 572; thus, the contact resistance between the channel formation region 570 and the source region 574 and the drain region 576 can be reduced.

Next, a protective layer 552 is formed over the transistor 562. The protective layer 552 can be formed by a sputtering method, a CVD method, or the like. The protective layer 552 can be formed using a material including an inorganic insulating material such as silicon oxide, silicon oxynitride, silicon nitride, hafnium oxide, or aluminum oxide.

Next, openings reaching the source region 574 and the drain region 576 are formed in the protective layer 552, the gate insulating layer 546, and the metal layers 542a and 542b. In the same step, an opening reaching the connection electrode layer 543 is formed in the protective layer 552 and the gate insulating layer 546. The openings are formed by selective etching with the use of a mask or the like.

Then, a wiring layer 580a which is in contact with the connection electrode layer 543 and the source region 574, and a wiring layer 580b which is in contact with the drain region 576 are formed in the openings. Note that the gate electrode layer 510 of the transistor 540 is electrically connected to the source region 574 of the transistor 562 through the wiring layer 580a.

The wiring layers 580a and 580b are formed in such a manner that a conductive film is formed by a PVD method such as a sputtering method or a CVD method such as a plasma CVD method and then the conductive layer is etched. Further, as a material of the conductive film, an element selected from Al, Cr, Cu, Ta, Ti, Mo, and W, an alloy containing any of the above elements, or the like can be used. Any of Mn, Mg, Zr, Be, Nd, and Sc, or a material containing any of these in combination may be used.

Next, an insulating layer 582 is formed over the protective layer 552 and the wiring layers 580a and 580b. An organic material such as polyimide, an acrylic resin, or a benzocyclobutene resin can be used for the insulating layer 582.

Then, openings reaching the wiring layers 580a and 580b are formed in the insulating layer 582. The openings are formed by selective etching with the use of a mask or the like.

Then, a wiring layer 584 which is in contact with the wiring layers 580a and 580b is formed in the opening. Note that the connection portion between the wiring layers 580a and 580b and the wiring layer 584 is not illustrated in FIG. 7A.

The wiring layer 584 can be formed with the material, method, and the like similar to those of the wiring layers 580a and 580b.

Through the above steps, the transistor 562 and the capacitor 564 are formed. The transistor 562 includes the oxide semiconductor layer 544 which is highly purified and contains excess oxygen that compensates an oxygen vacancy. Therefore, the transistor 562 has less change in electrical characteristics and thus is electrically stable. Further, the regions of the oxide semiconductor layer 544 where the channel formation region 570 is formed are thinner than the regions where the source region 574 and the drain region 576 are formed, by etching. Thus, the threshold voltage (Vth) can be adjusted in the positive direction.

Note that the capacitor 564 includes the connection electrode layer 543, the gate insulating layer 546, and the capacitor wiring layer 549. In addition, in the case where no capacitor is needed, a structure in which the capacitor 564 is not provided is also possible.

FIG. 7C is an example of a diagram of a circuit using the semiconductor device as a memory element. In FIG. 7C, one of a source electrode layer and a drain electrode layer of the transistor 562, one electrode of the capacitor 564, and a gate electrode of the transistor 540 are electrically connected to one another. A first wiring (1st Line, also referred to as source line) is electrically connected to a source electrode of the transistor 540. A second wiring (2nd Line, also referred to as bit line) is electrically connected to a drain electrode of the transistor 540. A third wiring (3rd Line, also referred to as first signal line) is electrically connected to the other of the source electrode and the drain electrode of the transistor 562. A fourth wiring (4th Line, also referred to as second signal line) is electrically connected to a gate electrode of the transistor 562. A fifth wiring (5th Line, also referred to as word line) is electrically connected to the other electrode of the capacitor 564.

The transistor 562 formed using an oxide semiconductor has extremely small off-state current; therefore, when the transistor 562 is in an off state, a potential of a node (hereinafter node FG) where the one of the source electrode and the drain electrode of the transistor 562, the one electrode of the capacitor 564, and the gate electrode of the transistor 540 are electrically connected to one another can be held for an extremely long time. The capacitor 564 facilitates holding of charge applied to the node FG and reading of stored data.

When data is stored in the semiconductor device (writing), the potential of the fourth wiring is set to a potential at which the transistor 562 is turned on, whereby the transistor 562 is turned on. Thus, the potential of the third wiring is supplied to the node FG and a predetermined amount of charge is accumulated in the node FG. Here, charge for applying either of two different potential levels (hereinafter referred to as low-level charge and high-level charge) is applied. After that, the potential of the fourth wiring is set to a potential at which the transistor 562 is turned off, whereby the transistor 562 is turned off. This makes the node FG floating and the predetermined amount of charge is held in the node FG. The predetermined amount of charge is thus accumulated and held in the node FG, whereby the memory cell can store data.

Since the off-state current of the transistor 562 is extremely small, the charge applied to the node FG is held for a long time. This can remove the need of refresh operation or drastically reduce the frequency of the refresh operation, which leads to a sufficient reduction in power consumption. Moreover, stored data can be held for a long time even when power is not supplied.

When stored data is read out (reading), while a predetermined potential (fixed potential) is supplied to the first wiring, an appropriate potential (reading potential) is supplied to the fifth wiring, whereby the transistor 540 changes its state depending on the amount of charge held in the node FG. This is because in general, when the transistor 540 is an n-channel transistor, an apparent threshold value Vₜₕ_{_{—}}_{H} of the transistor 540 in the case where the high-level charge is held in the node FG is lower than an apparent threshold value Vₜₕ_{_{—}}_{L} of the transistor 540 in the case where the low-level charge is held in the node FG. Here, an apparent threshold value refers to a potential of the fifth wiring, which is needed to turn on the transistor 540. Thus, by setting the potential of the fifth wiring to a potential V₀ which is between Vₜₕ_{_{—}}_{H} and Vₜₕ_{_{—}}_{L}, charge held in the node FG can be determined. For example, in the case where the high-level charge is applied in writing, when the potential of the fifth wiring is set to V₀ (>Vₜₕ_{_{—}}_{H}), the transistor 540 is turned on. In the case where the low level charge is applied in writing, even when the potential of the fifth wiring is set to V₀ (<Vₜₕ_{_{—}}_{L}), the transistor 540 remains in an off state. In such a manner, by controlling the potential of the fifth wiring and determining whether the transistor 540 is in an on state or off state (reading out the potential of the second wiring), stored data can be read out.

Further, in order to rewrite stored data, a new potential is supplied to the node FG that is holding the predetermined amount of charge applied in the above writing, so that the charge of new data is held in the node FG. Specifically, the potential of the fourth wiring is set to a potential at which the transistor 562 is turned on, whereby the transistor 562 is turned on. Thus, the potential of the third wiring (potential of new data) is supplied to the node FG, and the predetermined amount of charge is accumulated in the node FG. After that, the potential of the fourth wiring is set to a potential at which the transistor 562 is turned off, whereby the transistor 562 is turned off. Thus, charge of the new data is held in the node FG. In other words, while the predetermined amount of charge applied in the first writing is held in the node FG, the same operation (second writing) as in the first writing is performed, whereby the stored data can be overwritten.

The off-state current of the transistor 562 described in this specification can be sufficiently reduced by using an oxide semiconductor film which is highly purified and contains excess oxygen as the oxide semiconductor layer 544. Further, by using such a transistor, a semiconductor device in which stored data can be held for an extremely long time can be obtained.

Since the transistor 562 in this embodiment includes the oxide semiconductor layer in which the pair of low-resistance regions and the source and drain regions are provided with the channel formation region sandwiched between the pair of low-resistance regions, in a channel length direction, ON characteristics (e.g., the on-state current, the field effect mobility) of the transistor 562 is high and the transistor 562 is capable of high-speed operation and high-speed response. The thickness of the oxide semiconductor layer is different between the region where the gate electrode layer 548 is overlapped and the region where the source region and the drain region are formed. The oxide semiconductor layer is thinner in the region where the gate electrode layer is overlapped than in the regions where the source region and the drain region are formed. Further, the channel formation region is formed in the thin region of the oxide semiconductor layer. Since the region of the oxide semiconductor layer where the channel formation region is formed is made thin, the threshold voltage (Vth) can be adjusted in the positive direction. Thus, a normally-off semiconductor device can be obtained.

In addition, the channel formation region is provided between the pair of low-resistance regions; thus, an electric field applied to the channel formation region can be relieved. Further, the source region and the drain region are directly formed in the oxide semiconductor layer and in contact with the channel formation region through the low-resistance regions; thus, the contact resistance between the channel formation region and the source region and the drain region can be reduced.

This embodiment can be combined with any of the other embodiments as appropriate.

### Embodiment 6

A semiconductor device disclosed in this specification can be applied to a variety of electronic devices (including game machines). Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like. Examples of electronic devices each including the semiconductor device described in the above embodiments are described.

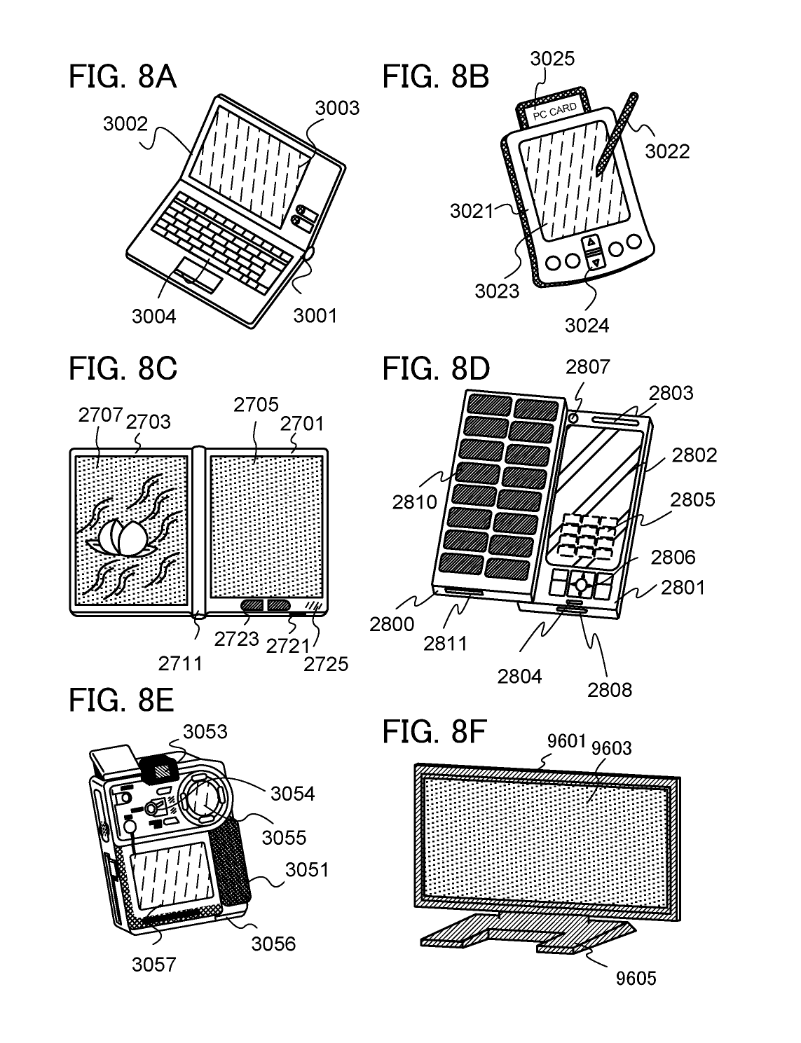

FIG. 8A illustrates a laptop personal computer, which includes a main body 3001, a housing 3002, a display portion 3003, a keyboard 3004, and the like. When the semiconductor device described in any of Embodiments 1 to 5 is applied to the display portion 3003, a highly reliable and high-performance laptop personal computer can be provided.

FIG. 8B is a personal digital assistant (PDA) including a display portion 3023, an external interface 3025, an operation button 3024, and the like in a main body 3021. A stylus 3022 is included as an accessory for operation. The semiconductor device described in any of Embodiments 1 to 5 is applied to the display portion 3023, whereby a highly reliable and high-performance personal digital assistant (PDA) can be provided.

FIG. 8C illustrates an e-book reader, which includes two housings, a housing 2701 and a housing 2703. The housing 2701 and the housing 2703 are combined with a hinge 2711 so that the e-book reader 2700 can be opened and closed with the hinge 2711 as an axis. With such a structure, the e-book reader 2700 can operate like a paper book.

A display portion 2705 and a display portion 2707 are incorporated in the housing 2701 and the housing 2703, respectively. The display portion 2705 and the display portion 2707 may display one image or different images. In the structure where different images are displayed in different display portions, for example, the right display portion (the display portion 2705 in FIG. 8C) can display text and the left display portion (the display portion 2707 in FIG. 8C) can display images. The semiconductor device described in any of Embodiments 1 to 5 is applied to the display portion 2705 and the display portion 2707, whereby a highly reliable and high-performance e-book reader can be provided. In the case of using a transflective or reflective liquid crystal display device as the display portion 2705, the e-book reader may be used in a comparatively bright environment; therefore, a solar cell may be provided so that power generation by the solar cell and charge by a battery can be performed. When a lithium ion battery is used as the battery, there are advantages of downsizing and the like.

FIG. 8C illustrates an example in which the housing 2701 is provided with an operation portion and the like. For example, the housing 2701 is provided with a power switch 2721, operation keys 2723, a speaker 2725, and the like. With the operation key 2723, pages can be turned. Note that a keyboard, a pointing device, or the like may also be provided on the surface of the housing, on which the display portion is provided. Furthermore, an external connection terminal (an earphone terminal, a USB terminal, or the like), a recording medium insertion portion, and the like may be provided on the back surface or the side surface of the housing. Moreover, the e-book reader 2700 may have a function of an electronic dictionary.

The e-book reader illustrated in FIG. 8C may transmit and receive data wirelessly. Through wireless communication, desired book data or the like can be purchased and downloaded from an electronic book server.

FIG. 8D illustrates a mobile phone, which includes two housings, a housing 2800 and a housing 2801. The housing 2801 includes a display panel 2802, a speaker 2803, a microphone 2804, a pointing device 2806, a camera lens 2807, an external connection terminal 2808, and the like. The housing 2800 includes a solar cell 2810 for charging the mobile phone, an external memory slot 2811, and the like. Further, an antenna is incorporated in the housing 2801. The semiconductor device described in any of Embodiments 1 to 5 is applied to the display panel 2802, whereby a highly reliable and high performance mobile phone can be provided.

The display panel 2802 is provided with a touch panel. A plurality of operation keys 2805 which is displayed as images is illustrated by dashed lines in FIG. 8D. Note that a boosting circuit by which a voltage output from the solar cell 2810 is increased to be sufficiently high for each circuit is also included.

In the display panel 2802, the display direction can be appropriately changed depending on a usage pattern. Further, the display device is provided with the camera lens 2807 on the same surface as the display panel 2802, and thus it can be used as a video phone. The speaker 2803 and the microphone 2804 can be used for videophone calls, recording and playing sound, and the like as well as voice calls. Moreover, the housing 2800 and the housing 2801 developed as illustrated in FIG. 8D can be slid so that one is lapped over the other; thus, the size of the mobile phone can be reduced, which makes the mobile phone suitable for being carried.

The external connection terminal 2808 can be connected to an AC adapter and various types of cables such as a USB cable, and charging and data communication with a personal computer are possible. Moreover, a large amount of data can be stored by inserting a storage medium into the external memory slot 2811 and can be moved.

In addition to the above functions, an infrared communication function, a television reception function, or the like may be provided.

FIG. 8E illustrates a digital video camera which includes a main body 3051, a display portion A 3057, an eyepiece 3053, an operation switch 3054, a display portion B 3055, a battery 3056, and the like. The semiconductor device described in any of Embodiments 1 to 5 is applied to the display portion (A) 3057 and the display portion (B) 3055, whereby a highly reliable and high performance digital video camera can be provided.

FIG. 8F is an example of a television set in which a display portion 9603 is incorporated in a housing 9601. The display portion 9603 can display images. Here, the housing 9601 is supported by a stand 9605. The semiconductor device described in any of Embodiments 1 to 5 is applied to the display portion 9603, whereby a highly reliable and high performance television set can be provided.

The television set illustrated in FIG. 8F can be operated by an operation switch of the housing 9601 or a separate remote control. Further, the remote controller may be provided with a display portion for displaying data output from the remote controller.

Note that the television set illustrated in FIG. 8F may be provided with a receiver, a modem, and the like. With the use of the receiver, general television broadcasting can be received. Moreover, when the display device is connected to a communication network with or without wires via the modem, one-way (from a sender to a receiver) or two-way (between a sender and a receiver or between receivers) information communication can be performed.

This embodiment can be combined with any of the other embodiments as appropriate.

This application is based on Japanese Patent Application serial no. 2011-134971 filed with Japan Patent Office on Jun. 17, 2011, the entire contents of which are hereby incorporated by reference.

What is claimed is:

1. A semiconductor device comprising:
an oxide semiconductor layer over an insulating surface, wherein the oxide semiconductor layer including a first region and a pair of second regions with the first region interposed therebetween;
a gate insulating layer over the oxide semiconductor layer; and
a gate electrode layer over the gate insulating layer,
wherein a source region and a drain region are formed in the pair of second regions,
wherein the first region is thinner than the pair of second regions and
wherein the first region includes a channel formation region overlapping with the gate electrode layer.

2. The semiconductor device according to claim 1, wherein an end portion of the first region is aligned with an end portion of the gate electrode layer.

3. The semiconductor device according to claim 1, further comprising:
a protective layer over the gate electrode layer; and
a wiring layer over the protective layer, wherein the wiring layer is electrically in contact with the source region and the drain region.

4. The semiconductor device according to claim 1, further comprising a metal layer electrically in contact with the source region and the drain region.

5. The semiconductor device according to claim 4, wherein an end portion of the metal layer is aligned with an end portion of the pair of second regions.

6. The semiconductor device according to claim 4, wherein an end portion of the metal layer is on an inner side than an end portion of the pair of second regions.

7. The semiconductor device according to claim 1, wherein the source region and the drain region include phosphorus or boron.

8. The semiconductor device according to claim 1, wherein the insulating surface is an oxide insulating surface.

9. A semiconductor device comprising:
an oxide semiconductor layer over an insulating surface, wherein the oxide semiconductor layer including a first region and a pair of second regions with the first region interposed therebetween;
a gate insulating layer over the oxide semiconductor layer; and
a gate electrode layer over the gate insulating layer,
wherein a source region and a drain region are formed in the pair of second regions, and
wherein the first region is thinner than the pair of second regions,
wherein the first region includes a channel formation region and a low-resistance region having lower resistance than the channel formation region,
wherein the channel formation region overlaps with the gate electrode layer, and
wherein the low-resistance region includes phosphorus or boron.

10. The semiconductor device according to claim 9, further comprising:
a protective layer over the gate electrode layer; and
a wiring layer over the protective layer, wherein the wiring layer is electrically in contact with the source region and the drain region.

11. The semiconductor device according to claim 9, further comprising a metal layer electrically in contact with the source region and the drain region.

12. The semiconductor device according to claim 11, wherein an end portion of the metal layer is aligned with an end portion of the pair of second regions.

13. The semiconductor device according to claim 11, wherein an end portion of the metal layer is on an inner side than an end portion of the pair of second regions.

14. The semiconductor device according to claim 9, wherein the source region and the drain region include phosphorus or boron.

15. The semiconductor device according to claim 9, wherein the insulating surface is an oxide insulating surface.

16. A method for manufacturing a semiconductor device comprising the steps of:
forming an oxide semiconductor layer over an insulating surface;
forming a mask over the oxide semiconductor layer;
selectively etching the oxide semiconductor layer with the use of the mask to form a first region and a pair of second regions in the oxide semiconductor layer with the first region interposed between the pair of second regions, wherein the first region is thinner than the pair of second regions;
forming a gate insulating layer over the oxide semiconductor layer; and
forming a gate electrode layer overlapping with the first region over the gate insulating layer.

17. The method for manufacturing a semiconductor device according to claim 16, further comprising the step of:
introducing phosphorus or boron into the oxide semiconductor layer through the gate insulating layer, with the use of the gate electrode layer as a mask to form a source region and a drain region in part of the oxide semiconductor layer.

18. The method for manufacturing a semiconductor device according to claim 16, wherein oxygen is introduced into the oxide semiconductor layer through the gate insulating layer after the gate insulating layer is formed.

19. The method for manufacturing a semiconductor device according to claim 16, wherein the insulating surface is an oxide insulating surface.

20. A method for manufacturing a semiconductor device comprising the steps of:
forming a stack of an oxide semiconductor layer and a metal layer over an insulating surface;
forming a mask over the metal layer;
removing part of the metal layer with the use of the mask;
selectively etching the oxide semiconductor layer with the use of the metal layer as a mask to form a first region and a pair of second regions in the oxide semiconductor layer with the first region interposed between the pair of second regions,
wherein the first region is thinner than the pair of second regions;
forming a gate insulating layer over the metal layer and the oxide semiconductor layer; and
forming a gate electrode layer overlapping with the first region, over the gate insulating layer.

21. The method for manufacturing a semiconductor device according to claim 20, further comprising the step of:
introducing phosphorus or boron into the oxide semiconductor layer through the gate insulating layer and the metal layer, with the use of the gate electrode layer as a mask to form a source region and a drain region in part of the oxide semiconductor layer.

22. The method for manufacturing a semiconductor device according to claim 20, wherein oxygen is introduced into the oxide semiconductor layer through the gate insulating layer after the gate insulating layer is formed.

23. The method for manufacturing a semiconductor device according to claim 20, wherein the insulating surface is an oxide insulating surface.
